SEQUENCE LISTING (9 sequences)

SEQ ID NO: 1 - DNA, 60 bp, Artificial
  Synthetic
gatttggggttcaaagcagtatcgatcaaatagtaaatccatttgttcaactcacagttt

SEQ ID NO: 2 - DNA, 45 bp, Artificial
  Synthetic
agcatgttagataagatagctgtgctagtaggcagtcagcgccat

SEQ ID NO: 3 - DNA, 17 bp, Artificial
  Synthetic
ttagataaaggatactg

SEQ ID NO: 4 - DNA, 14 bp, Artificial
  Synthetic
aaaagataaggata

SEQ ID NO: 5 - DNA, 11 bp, Artificial
  Synthetic
gcctaagctaa

SEQ ID NO: 6 - DNA, 11 bp, Artificial
  Synthetic
atagcttcagc

SEQ ID NO: 7 - DNA, 11 bp, Artificial
  Synthetic
ttagcttaggc

SEQ ID NO: 8 - DNA, 9 bp, Artificial
  Synthetic
cagcggcat

SEQ ID NO: 9 - DNA, 5 bp, Artificial
  Synthetic
taggc

(19) United States
(12) Patent Application Publication
(10) Pub. No.: US 2018/0152535 A1
(43) Pub. Date: May 31, 2018

(54) STORAGE, TRANSFER AND COMPRESSON OF NEXT GENERATION SEQUENCING DATA

(71) Applicant: Geneformics Data Systems Ltd., Ramat Efal (IL)

(72) Inventors: Dan Sade, Hod Hasharon (IL); Shai Lubliner, Tel Aviv (IL); Arie Keshet, Ramat Efal (IL); Eran Segal, Ramat Hasharon (IL); Itay Sela, Tel Aviv (IL)

(21) Appl. No.: 15/568,801

(22) PCT Filed: May 2, 2016
(86) PCT No.: PCT/IL2016/050455

§ 371 Date: Oct. 24, 2017

Related U.S. Application Data
(60) Provisional application No. 62/164,651, filed on May 21, 2015.
(60) Provisional application No. 62/164,611, filed on May 21, 2015.

(51) Int. Cl. H04L 29/08; G06F 19/28

(52) U.S. Cl. CPC H04L 67/2828; H04L 67/1097; H03M 7/60; G06F 19/28; H04L 67/06

(57) ABSTRACT

A computer appliance including a front-end interface communicating with a client computer, a back-end interface communicating with a storage, a compressor receiving native next generation sequencing (NGS) data from an application running on the client computer via the front-end interface, the application being programmed to process native NGS data, adding a compressed form of the native NGS data into a portion of an encoded data file or data object, and storing the portion of the encoded data file or data object in the storage via the back-end interface, and a decompressor receiving a portion of an encoded data file or data object from the storage via the back-end interface, decompressing the portion of the encoded data file or data object to generate therefrom native NGS data, and transmitting the native NGS data to the client via the front-end interface, for use by the application running on the client.

### CROSS REFERENCES TO RELATED APPLICATIONS

This application is a national phase entry of international application PCT/IL2016/050455, entitled STORAGE, TRANSFER AND COMPRESSION OF NEXT GENERATION SEQUENCING DATA, filed on May 2, 2016 by inventors Dan Sade, Shai Lubliner, Arie Keshet, Eran Segal and Itay Sela.

PCT/IL2016/050455 claims benefit of U.S. Provisional Application No. 62/164,611, entitled COMPRESSION OF GENOMICS FILES, and filed on May 21, 2015 by Shai Lubliner, Arie Keshet and Eran Segal, the contents of which are hereby incorporated herein in their entirety.

PCT/IL2016/050455 claims benefit of U.S. Provisional Application No. 6²/₁64,651, entitled STORAGE OF COMPRESSED GENOMICS FILES, and filed on May 21, 2015 by inventors Danny Sade and Arie Keshet, the contents of which are hereby incorporated herein in their entirety.

### FIELD OF THE INVENTION

The present invention relates to efficient storage and transfer of next generation sequencing data.

### BACKGROUND OF THE INVENTION

Tremendous progress over the past decade in the technology and adoption of next generation sequencing (NGS) has brought with it a rapid decline in cost, to the point where the price in 2015 of high-coverage sequencing of a whole human genome was $1,000. In parallel, scale has been growing quickly and the genomes of 228,000 individuals have been sequenced in 2014. Global NGS capacity has doubled every 7 months in recent years and is projected to continue to double every 12 months in the near to medium-term future.

NGS is generating raw data at a rate that is projected to grow to 2-40 exabytes per year by 2025, eclipsing all other fields of science and technology. This raw data, while meant to undergo reduction by downstream processing, is nevertheless extensively shared and almost always archived. Its storage, transfer and management represent, therefore, a technological and economical challenge to the continued development of NGS. Data compression has proved to be an invaluable tool in many fields of technology, and it will play a key role in NGS.

### Native NGS Data Formats

The bulk of NGS data is stored in files conforming to one of a handful of de-facto standards. Reference is made to FIG. 1, which is a prior art illustration of an exemplary FASTQ machine output read, an exemplary alignment, and an exemplary SAM file representing the exemplary alignment.

FASTQ is the de-facto standard file format for storing the output data of NGS machines. FASTQ files are text-based and each machine output read is represented by four lines of text, as shown in FIG. 1. Line 1 begins with a ‘@’ character and is followed by a read identifier and an optional description. Line 2 contains the bases of the read—A, C, G, T, or N (undetermined). Line 3 begins with a ‘+’ character, which is optionally followed by the same read identifier as in line 1. Line 4 encodes the quality scores for the bases in Line 2 and must have the same length. A quality score represents the estimated probability of error in the corresponding base according to the Phred scale, encoded into a printable character.

SAM (Sequence Alignment/Map) and BAM (Binary Alignment/Map) are the de-facto file formats used to store the output of short-read alignment programs such as BWA and Bowtie. SAM specifies a text format consisting of a header section, which is optional, followed by one or more alignment sections, reporting each on the alignment of one read, as shown in FIG. 1. Each header section line, or record, begins with the character ‘@’ followed by a two-letter record type code. With one exception, used for commenting, each record consists of a TAB-delimited series of data fields. Each such field follows a format ‘TAG:VALUE’, where TAG is a two-character string that defines the format and content of VALUE. Various header record types provide information on:
the format version of the file and the sorting order of the alignment sections;
the name, length and pointer to the reference genome(s) used for alignment;
the sequencing run(s) that produced the read group(s) in the file (identified by organization, platform, date); and
the program that produced the SAM file.
   The user is allowed to define additional types of header records and data fields.

Each alignment section consists of a line of text that represents the result of the alignment of one read, as shown in FIG. 1. Reads r001/1 and r001/2 are a read pair, r003 is a chimeric read, and r004 represents a split alignment. Bases in lower case were clipped from the alignment. Two of the SAM file lines were split and indented for ease of reading.

An alignment section contains 11 mandatory fields that provide information on:
the name of the read (which may appear multiple times, one for each candidate mapping);
flags reporting on the alignment of the companion paired read;
the name of the reference genome against which the read is mapped;
the estimated position of the read in the reference genome;
the quality (or probability or error) of the mapping decision;
a “CIGAR” string, reporting on misalignments (insertions or deletions) between the read and the reference genome;
the reference genome against which the companion paired read is mapped;
the position of the companion paired read in the above reference genome;
the length of the DNA segment that yielded the paired reads;
the read base sequence (as appear in the FASTQ file); and
the quality scores of the read bases in the FASTQ file. (Quality scores are omitted from the example in FIG. 1 for ease of reading). A number of optional alignment section fields are also defined.

BAM is a compressed version of SAM. A BAM file is created by dividing a SAM file into blocks of up to 64 Kbytes, compressing each block to a gzip archive and concatenating the archives to create a single output file. In order to support random read operations into the BAM file, a companion BAM Index (BAI) file may also be created. For this purpose, the alignment sections in the SAM file must be ordered by position in the genome, and the BAI file contains a data structure that efficiently maps a position or a range within the genome to the offset in the BAM file of the relevant gzip block or blocks.

### Compression Algorithms

A number of algorithms form the basis of many lossless NGS data compression schemes.

One algorithm used for NGS data compression is word substitution. A field within a data format, also referred to as a symbol, may sometimes be longer than the number of bits strictly needed to encode its alphabet—the set of values that it can take. In such a case, a one-to-one mapping can be defined from each letter of the alphabet to a value of a shorter corresponding field that will be incorporated into the compressed format. E.g., FASTQ uses a byte to encode either one of the four DNA bases or an undefined readout (‘N’). This set of five letters can be encoded by just 3 bits. As 3 bits can actually represents 8 different letters, the compression ratio can be improved by using 7 bits to encode a triplet of bases, bringing efficiency up from 5/8 to 5³/2⁷ (125/128, or 98%).

Another algorithm used for NGS data compression is probability-weighted encoding. The ratio of compression can be improved beyond what is achievable by word substation in cases where the letters of a symbol's alphabet occur at unequal, but known, probabilities. Huffman coding maps symbols to variable-length code-words so that shorter code-words represent higher-probability letters and vice versa.

Reference is made to FIG. 2, which is a prior art illustration of an exemplary Huffman code binary tree. In the example shown in FIG. 2, symbols A, B and C occur with probabilities 0.5, 0.25 and 0.25, respectively. Huffman coding is optimal when these are encoded to 0, 10 and 11, respectively. In order to allow unambiguous decompression, no code-word can be a prefix of another: thus, if 0 represents A in the above example, all other code-words must begin with 1, and so on for larger dictionaries with longer code-words.

A Huffman code is designed by building a binary tree, starting with a set of unconnected leaf nodes representing each a letter of the symbol's alphabet. In the first step of the process, a new branch node is formed to serve as the parent of the two leaf nodes with the lowest combined probability. The newly created node is assigned the sum of the probabilities of its two child nodes. This process is repeated for the set of nodes at the roots of the sub-trees that are still unconnected, until they are all connected by the global root node. Starting now at the root, code-word prefixes are assigned to the branches of the tree by adding 0 or 1 to the prefix of the branch leading to the parent node. For the single branch node in FIG. 2, the incoming branch is labeled 1 and the outgoing branches 10 and 11. Finally, each letter is encoded by the code-word assigned to the branch leading to it.

Modern sequencing machines generally assign a high quality score to the majority of decoded bases: for Illumina software, Version 1.8 and later, scores ‘A’ through ‘J’ (32 through 41 on the Phred scale) are, in most datasets, more common than ‘!’ through ‘@’. Huffman coding of quality scores improves compression ratio beyond that achievable by word substitution (which only takes advantage of the fact that the 42 quality score letters can be encoded by 5.4 instead of 8 bits).

The design of a Huffman code is restricted by the fact that the lengths of code-words are discrete; a Huffman code will only be optimal when all symbol probabilities are powers of 1/2. Encoding groups of symbols can improve efficiency, but at a cost of exponential increase in tree size. Arithmetic coding is an improvement over Huffman coding in this respect.

Arithmetic coding is based on the concept of dividing the interval [0, 1) to sub-intervals, one for each letter of the alphabet. The length of each interval is set to equal the probability of the letter it represents. Thus, for the example shown in FIG. 2 with symbols A, B, and C, the set of intervals may be [0, 0.5), [0.5, 0.75) and [0.75, 1). Reference is made to FIG. 3, which is a prior art illustration of an arithmetic encoder and decoder for this example.

An arithmetic encoder is initialized with a state variable representing the interval [0, 1). The first symbol in the block to be compressed is read and the interval is narrowed to the sub-interval representing the symbol to be encoded, say [0.5, 0.75) for B. When the next symbol is read, the current interval is again narrowed to represent the relative sub-interval corresponding to the second symbol. Thus, if the second symbol is A then [0.5, 0.75) is narrowed down to [0.5, 0.625). This procedure is repeated for each successive symbol, yielding an ever narrower interval. At the end of the block of symbols, the output of the encoder is the number within the final interval that requires the least bits to encode. The number of output bits will be in inverse proportion to the size of the final interval and therefore to the joint probability of the letters in the block.

The arithmetic decoder too is provided with the mapping of letters to intervals. As shown in FIG. 3, the decoder starts by determining the letter interval within [0, 1) into which the encoder output falls; this interval represents the first decoded symbol, say B. The decoder now “pulls B out” of the decoder input by linearly mapping both the letter interval and the input within the interval back to [0, 1); e.g., if the encoder output was 0.51, back-scaling the interval [0.5, 0.75) representing B to [0, 1) maps the encoder output to 0.04 ((0.51-0.5)/(0.75-0.5)). This process is repeated for the newly computed code-word (0.04) until the prescribed number of symbols has been decoded.

Practical implementations of arithmetic coding are designed to produce interim outputs from the encoder as well as decoder. Arbitrarily long sequences of symbols can therefore be encoded and decoded with bounded memory requirements and delay.

It is well known that the DNA of most organisms has unequal proportions of the four bases (e.g., approximately 0.3, 0.3, 0.2 and 0.2 for A, T, C and G in the human genome). Arithmetic coding makes use of this information to compress the bases of FASTQ reads.

Yet another algorithm used for NGS data compression is context encoding. In many situations, the value of a symbol in a block of symbols to be compressed will be statistically correlated with the value of the preceding symbol or symbols. E.g., quality scores along a read will tend to show relatively small changes from one symbol to the next. Context encoding makes use of this information to improve compression ratio.

When processing a symbol, a Huffman or arithmetic encoder can be instructed to pick one out of a number of probability distributions (sets of letter likelihoods). If this choice is made based on information that is also available to the decoder, the encoder and decoder can be run in lockstep and ensure correct reconstruction of the original symbol. E.g., past symbols will already have been decoded by the decoder and can therefore form such a context for encoding.

Returning to the example of quality score lines in a FASTQ file, and keeping in mind the tendency of quality scores to change slowly over a read, a ‘J’ might most likely be followed by a ‘J’. Thus, encoding the symbol following a ‘J’ might best be done with a probability distribution that peaks at ‘J’, while symbols following other letters might use different distributions. As long as the encoder and decoder are provided with the same set of rules, they use the same probability distributions and thus stay in sync.

Refining the context, e.g., by using more than one past symbol, may improve the accuracy of the probability model. However, this comes at the expense of encoder and decoder memory. If no context is used, the probability distribution of quality scores must specify 42 entries. With one past quality score symbol as a context this increases to 42², continuing to grow exponentially with the number of context symbols.

Yet another algorithm used for NGS data compression is adaptive encoding. In most situations, symbol probability distributions are not known exactly. Continuing with the quality scores example, while a skewed distribution that favors high values is most likely to better represent the data than a uniform distribution, its shape will vary with sequencing machine model and sample characteristics. Arithmetic coding can be enhanced to adapt to symbol probabilities that are unknown a-priory.

To operate adaptively, an arithmetic encoder keeps a table of running counts for each letter of the symbols' alphabet. When implementing context encoding adaptively, a separate such table is kept for each context (i.e., each possible set of context symbol values). Before encoding a symbol in a certain context, the current entries of that context' table are translated to a probability measure by dividing each by the sum of all table entries. These probabilities are used to encode the symbol as explained above, following which the count of the letter that was just encoded is increased. At start-up, the tables are initialized to a uniform (small) count that represents a uniform probability distribution or to another estimated distribution. A fixed deterministic rule is employed to perform periodic down-scaling of table entries to avoid overflow. The decoder maintains similar tables that are similarly initialized and normalized, and uses each decoded symbol to update the corresponding count. This ensures that the encoder and decoder operate in a coordinated fashion, adapting to the actual symbol probability distribution without requiring any side-information to be included in the compressed data.

Yet another algorithm used for NGS data compression is dictionary encoding. The ZIP file format, generated by a class of compatible lossless compression algorithms, is the best-known example of dictionary encoding. Its popularity stems from its fair performance on many types of data without requiring any characterization or prior information on that data.

As its name suggests, a dictionary encoder builds and maintains a dictionary of data sequences that it has previously encountered in the input data. At any point during the encoding process, the encoder will search for the longest dictionary entry that matches the next several symbols to be encoded. It will then, (i) encode these input symbols by the index into the dictionary of the matching entry; (ii) add a new entry into the dictionary created from the above matching entry concatenated with the immediately following symbol; and (iii) continue processing input data starting from the symbol immediately following the matching string. At initialization, the dictionary must contain an entry for each letter of the symbols' alphabet. A dictionary maintenance algorithm must run in parallel with encoding to keep its size under a pre-determined limit.

E.g., a dictionary encoder processing the binary stream
01000011 . . .
   must be initialized with dictionary entries for 0 and 1, and during encoding will add dictionary entries
01, 10, 00, 000, 011 . . .
   while outputting the indexes of dictionary entries
0, 1, 0, 00, 01 . . . .
   The decoder performs the reverse operation of dictionary look-up by index. As long it employs the same rule for dictionary-entry addition and the same maintenance algorithm, it will be able to maintain a copy of the dictionary that will be consistent with the encoder's.

### FASTQ Compression

FASTQ files are often compressed by ZIP-compatible software such a gzip, which typically achieves a compression ratio of 2.5-3.5. As with other types of data, tuning the compression algorithm to its specific characteristics will improve compression.

G-SQZ pairs each FASTQ base with its corresponding quality score and uses Huffman coding to encode the combined two-part symbols. During a first pass over the file, the frequency distribution of all possible pair values is determined, serving as the basis for a Huffman code that is used during a second pass to encode the contents of read and quality score lines. Read identifiers are encoded separately, making use of recurring fields in adjacent identifiers.

KungFQ and FQC use an approach based on separately pre-processing the identifier, read and quality score lines; merging the three interim streams; and compressing the result with a ZIP-compatible encoder. Identifiers conforming to specific popular formats are delta encoded, but are left unchanged in other cases. Quality scores are encoded by run-length coding: long repetitions are encoded to the quality score value and number of repetitions. Bases are encoded by either triple-symbol word substitution or by run-length coding.

DSRC2 implements a selection of compression schemes: bases are encoded by either word substitution, Huffman coding or arithmetic coding. Quality scores are encoded by one of: Huffman coding in the context of position within the read; Huffman coding in the context of the preceding symbol or run-length of symbols; or, arithmetic coding in the context of preceding symbols.

SCALCE attempts to identify redundancy that exists in overlapping reads that come from a high-coverage sample. For this purpose, it uses Locally Consistent Parsing (LCP) to pre-process reads prior to encoding: for each read, LCP identifies the longest substring (or substrings) that it shares with other reads. Reads are clustered based on shared strings and, within the cluster, ordered by the position of the shared string within the read. Finally, the reads are encoded in the above order by a ZIP-compatible encoder.

Quip performs de novo assembly (assembly without a reference genome) of reads into ‘contigs’, which are relatively long, contiguous sections of DNA. Reads are then encoded to their position within a contig. De novo assembly generally relies on de Bruijn graphs, and is memory-intensive. Quip uses a probabilistic data structure that is more efficient, at the cost of occasional miscalculations of k-mer counts. These result in failed assembly but only mean less efficient encoding of the few affected reads.

When a FASTQ file contains reads from a known organism, then if a read: (i) can be mapped to the right location in that organism's genome; and (ii) contains a limited number of mutations or sequencing errors; then the read's base sequence can be efficiently encoded by the combination of its position within the reference genome and the set of mismatches between them. This is called referenced-based coding.

SlimGene and samcomp read a SAM/BAM file that reports on the mapping of reads to the reference genome and encode a read's mapping position and mismatches to a combination of opcodes and offset values.

Fastqz and LW-FQZip include ‘lightweight’ mappers that attempt to find the location of each read in a reference genome. Mapping is based on creating an index of k-mers appearing in the reference genome. Each read is scanned base-by-base for a k-mer that is present in the index and, if a match is found, the rest of the read is compared against the reference genome to identify mismatches.

To encode identifiers, unmapped reads and quality scores, fastqz uses ZPAQ, arithmetic coding software that includes a sophisticated toolbox of context modeling. ZPAQ is a bit-by-bit encoder, further slowed by its complex context modeling algorithm. To speed up encoding and decoding, fastqz includes a pre-processing step that marks up repeating prefixes in identifiers and pre-encodes runs of quality-score values.

### BAM Compression

As with FASTQ, specially tuned algorithms improve BAM compression ratio beyond gzip's.

SAMZIP separately optimizes the encoding of each alignment section tag, using combinations of delta, Huffman and run-length coding. Quality scores are run-length encoded.

NGC assumes availability of the reference genome and only explicitly encodes base mismatches. This is done by traversing read sequences ‘vertically’, i.e., in order of position in the reference genome and then read alignment position (i.e. starting position of the read). The mismatches are run-length encoded.

DeeZ encodes quality scores with an arithmetic coder. As to read sequences, DeeZ assumes that the majority of differences in bases between a read and its mapping locus on the reference genome are due to mutations (rather than sequencing errors) and are therefore shared with other reads mapped to the same locus. DeeZ obtains the ‘consensus’ of the reads mapped to a specific locus and encodes the differences between the consensus contigs and the reference genome only once.

CRAM defines a set of encoding algorithms that can be used to encode different SAM fields. The set includes beta (word substitution), run-length defined by either count or stop value, Huffman, Elias gamma (exponential), sub-exponential (linear and exponential sub-ranges), and Golomb or Golomb-Rice coding. In addition, CRAM allows the use of external data for rANS, a range-coder variant of Asymmetric Numerical System coding.

ADAM is one of several schemes that reformat a set of BAM files as a data structure that resembles a columnar database. This speeds up searches across multiple files for reads aligned to a given area in the genome. The columnar arrangement means that similar fields in a file and across files are now adjacent, providing an opportunity for more efficient representation. ADAM and similar schemes, however, are not compatible with BAM, requiring a re-write of file operations in all relevant applications.

### SUMMARY

Lossless compression is an invaluable tool in addressing the challenges inherent in the sheer volume of NGS data.

Various embodiments of the present invention losslessly compress FASTQ files at high compression ratios and fast processing rates, and are effective in application-transparent infrastructure products.

Identifier, read sequence and quality score lines are compressed by separately tuned algorithms, the outputs of which are combined into a single compressed file.

Identifier compression is completely general, while optimized for the most common format variations. Identifiers are tokenized and tokens are analyzed for common patterns such as repeats and constant increments. The result is then arithmetically encoded.

An internal, fast mapper maps read sequences to a reference genome. The mapper is orders of magnitude faster than BWA and Bowtie while achieving a 95% typical success rate for real-life data. For samples that do not come from a known organism, as well as for unmapped reads, the encoder uses a multi-variable, DNA-sequence optimized arithmetic coder.

Quality scores are encoded by an adaptive arithmetic coder that uses a complex, multi-variable context comprising, among others, preceding scores, position in the read and specific characteristics of different sequencing machine technologies.

Embodiments of the present invention perform encoding and decoding in streaming mode. This make is possible for a storage server, a cloud server and a transporter to pipeline encoding/decoding with file serving, reducing to a minimum start-up delay and application response time.

Alternative embodiments of the present invention losslessly compress BAM files, drastically reducing their size for storage and transport. These embodiments are of advantage for infrastructure products that remain transparent to applications, by serving them with native format unmodified BAM files.

Separately tuned algorithms are used to encode the various BAM tag-value fields.

The redundancy that exists between reads and alignment/mapping tags is efficiently eliminated by reference-based coding, without requiring the presence of the reference genome that was originally used in creating the BAM file.

Quality scores are encoded with a multi-variable context, adaptive arithmetic encoder. The present invention resolves the inherent conflict between, on the one hand, the large encoding block size needed to train complex adaptive encoders and, on the other, the small block size needed for efficient random access for file read.

There is thus provided in accordance with an embodiment of the present invention a computer appliance for storage, transfer and compression of next generation sequence (NGS) data, including a front-end interface communicating with a client computer via a first storage access protocol, a back-end interface communicating with a storage system via a second storage access protocol, a compressor receiving native NGS data from an application running on the client computer via the front-end interface, adding a compressed form of the native NGS data into a portion of an encoded data file or data object, and storing the portion of the encoded data file or data object in the storage system via the back-end interface, and a decompressor receiving a portion of an encoded data file or data object from the storage system via the back-end interface, decompressing the portion of the encoded data file or data object to generate therefrom native NGS data, and transmitting the native NGS data to the client via the front-end interface, for use by the application running on the client.

There is additionally provided in accordance with an embodiment of the present invention a non-transitory computer readable medium storing instructions, which, when executed by a processor of a computer appliance, cause the processor to, in response to receiving a write request from an application running on a client computer, obtain native NGS data from the application, read a portion of an encoded data file or data object from a storage system, modify the portion of the encoded data file or data object, including adding a compressed form of the native NGS data into the portion of the encoded data file or data object, and transmit the modified portion of the encoded data file or data object for storage in the storage system, and, in response to receiving a read request from the application, read a portion of an encoded data file or data object from the storage system, decompress the portion of the encoded data file or data object and generate therefrom native NGS data, and transmit the native NGS data to the application.

### BRIEF DESCRIPTION OF THE DRAWINGS

The present invention will be more fully understood and appreciated from the following detailed description, taken in conjunction with the drawings in which:

FIG. 1 is a prior art illustration of an exemplary FASTQ machine output read, an exemplary alignment, and an exemplary SAM file representing the exemplary alignment;

FIG. 2 is a prior art illustration of an exemplary Huffman code binary tree;

FIG. 3 is a prior art illustration of an exemplary arithmetic encoder and decoder;

FIG. 4 is a simplified block diagram of a system for storage, transfer and compression of next generation sequencing (NGS) data, in accordance with an embodiment of the present invention;

FIG. 5 is a simplified block diagram of processes and threads run by the system of FIG. 4, in accordance with an embodiment of the present invention;

FIG. 6 is a state transition diagram for the five states of a cached FASTQ and BAM file, in accordance with an embodiment of the present invention;

FIG. 7 is a simplified flowchart of a method for performing a WRITE operation, performed by an NGS storage, transfer and compression system, in accordance with an embodiment of the present invention;

FIG. 8 is a simplified flowchart of a method for performing a READ operation, performed by an NGS storage, transfer and compression system, in accordance with an embodiment of the present invention;

FIG. 9 is a simplified flowchart of a method for performing a CREATE DIRECTORY operation, performed by an NGS storage, transfer and compression system, in accordance with an embodiment of the present invention;

FIG. 10 is a simplified flowchart of a method for performing a DELETE DIRECTORY operation, performed by an NGS storage, transfer and compression system, in accordance with an embodiment of the present invention;

FIG. 11 is a simplified flowchart of a method for performing a RENAME DIRECTORY operation, performed by an NGS storage, transfer and compression system, in accordance with an embodiment of the present invention;

FIG. 12 is a simplified flowchart of a method for performing a CREATE FILE operation, performed by an NGS storage, transfer and compression system, in accordance with an embodiment of the present invention;

FIG. 13 is a simplified flowchart of a method for performing a DELETE FILE operation, performed by an NGS storage, transfer and compression system, in accordance with an embodiment of the present invention;

FIG. 14 is a simplified flowchart of a method for performing a RENAME FILE operation, performed by an NGS storage, transfer and compression system, in accordance with an embodiment of the present invention;

FIG. 15 is a simplified flowchart of a method for performing a READ DIRECTORY CONTENT operation, performed by an NGS storage, transfer and compression system, in accordance with an embodiment of the present invention;

FIG. 16 is a simplified flowchart of a method for performing a READ FILE ATTRIBUTES operation, performed by an NGS storage, transfer and compression system, in accordance with an embodiment of the present invention;

FIG. 17 is a simplified flowchart of a method for performing a WRITE FILE ATTRIBUTES operation, performed by an NGS storage, transfer and compression system, in accordance with an embodiment of the present invention;

FIG. 18 is a simplified flowchart of a method for performing a READ FILE SYSTEM INFORMATION operation, performed by an NGS storage, transfer and compression system, in accordance with an embodiment of the present invention;

FIG. 19 is a simplified flowchart of a method for two-pass compression of native NGS data, in accordance with an embodiment of the present invention;

FIG. 20 is a simplified flowchart of a method for stateful compression of native NGS data, in accordance with an embodiment of the present invention;

FIG. 21 is a simplified flowchart of a method for two-pass alignment compression of native NGS data, in accordance with an embodiment of the present invention;

FIG. 22 is a simplified flowchart of a method for out-of-field context compression of native NGS data, in accordance with an embodiment of the present invention;

FIG. 23 is a simplified flowchart of a method for order-based compression of native NGS data, in accordance with an embodiment of the present invention;

FIG. 24 is a simplified flowchart of a method for parallel processing compression of native NGS data, in accordance with an embodiment of the present invention;

FIG. 25 is a simplified flowchart of a method for barcode-based compression of native NGS data, in accordance with an embodiment of the present invention;

FIG. 26 is a simplified flowchart of a method for de-duplication compression of native NGS data, in accordance with an embodiment of the present invention; and

FIG. 27 is an illustration of a hardware version of the appliance of FIG. 4, showing front panel and back panel interfaces, in accordance with an embodiment of the present invention;

FIG. 29 is an exemplary IP address configuration for the hardware appliance of FIG. 27, in accordance with an embodiment of the present invention; and

FIG. 29 is a sample of summary information output by the hardware appliance of FIG. 27, in accordance with an embodiment of the present invention.

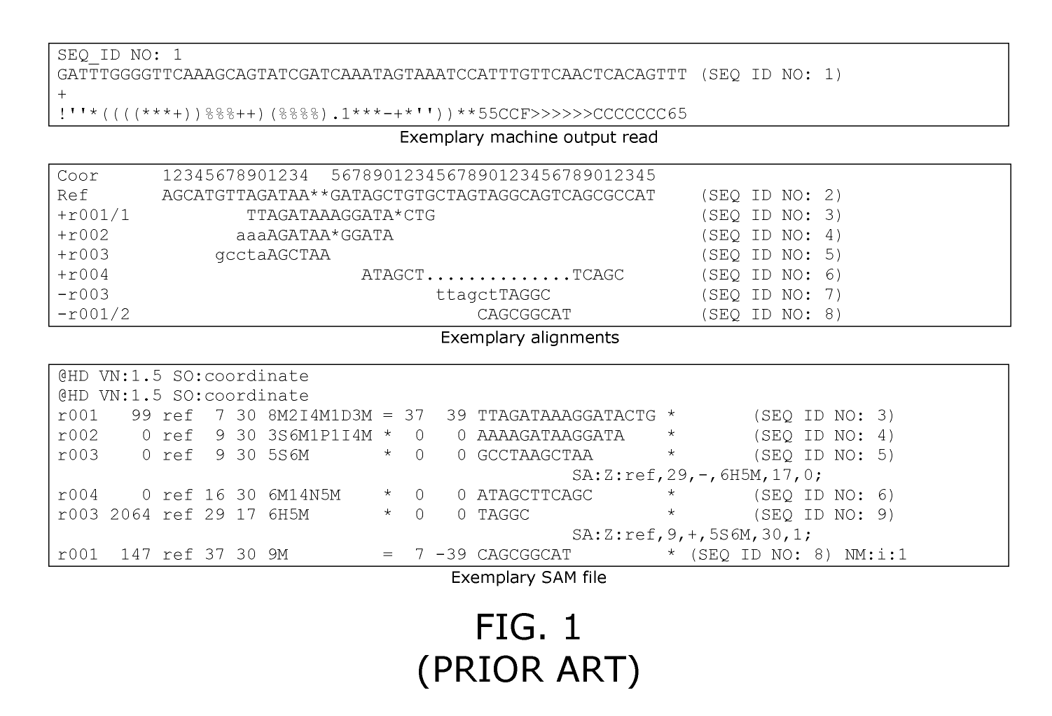

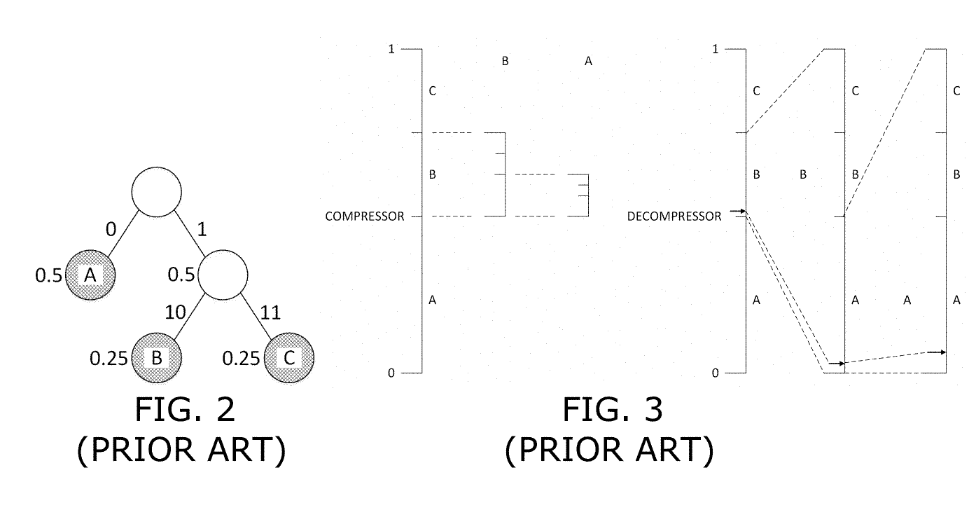

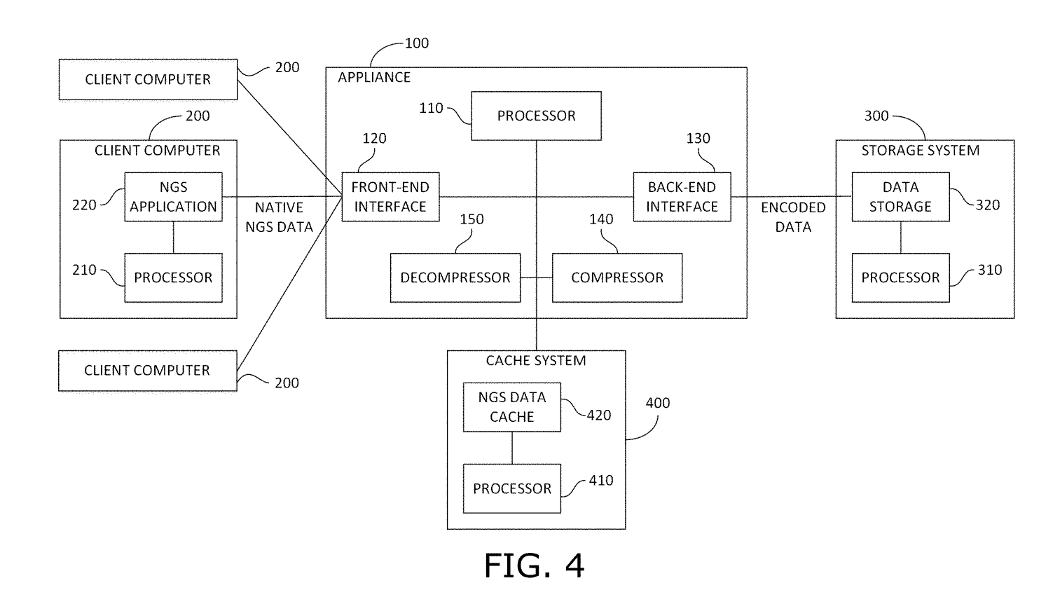

For reference to the figures, the following index of elements and their numerals is provided. Similarly numbered elements represent elements of the same type, but they need not be identical elements.

Table of elements in the figures

| Element | Description |
|---|---|
| 100 | computer appliance |
| 110 | processor |
| 111 | proxy process |
| 112 | compression/decompression process |
| 116 | server thread |
| 117 | connection threads |
| 118 | master thread |
| 119 | compression/decompression threads |
| 120 | front-end interface with client computer |
| | (first storage access protocol) |
| 130 | back-end interface with storage system |
| | (second storage access protocol) |
| 140 | compressor |
| 150 | decompressor |
| 200 | client computer |
| 210 | processor |
| 220 | next generation sequencing (NGS) application |
| 300 | storage system |
| 310 | processor |
| 320 | file-based/object-based storage |
| 400 | cache system |
| 410 | processor |
| 420 | Cache |
| 500 | hardware appliance |
| 520 | front panel of appliance |
| 521 | power on indicator, power button |
| 522 | non-maskable interrupt (NMI) button |
| 523 | system identification button |
| 524 | USB management ports |
| 525 | optical drive (optional) |
| 526 | SD vFlash media card slot |
| 527 | LCD menu buttons |
| 528 | information tag |
| 529 | LCD panel |
| 531 | video output |
| 532 | hard drive bays |
| 533 | mounting brackets |
| 540 | back panel of appliance |
| 541 | system identification button |
| 542 | system identification port |
| 543 | dedicated management port |
| 544 | PCIe expansion card slot |
| 545 | serial communication port |
| 546 | video output |
| 547 | USB connectors (2) |
| 548 | PCIe expansion card slot |
| 549 | LAN ports |
| 551 | power supply |
| 552 | hot-spare power supply |

Elements numbered in the 1000's and 2000's are operations of flow charts.

The following definitions are employed throughout the specification.
ALIGNER—a software or hardware processor that receives as input a machine output file and generates as output an alignment file that reconstructs, from reads in the machine output file, the structure of the complete NA molecule from which the reads came.
ALIGNMENT FILE—file that contains, for each read in a machine output file, a location within the NA molecule from which the read came from, and any differences between the read and the location in the molecule.
BAM—a file format that is a standard compressed version of a SAM file
BASE—one nucleotide in a nucleic acid. Thus, DNA consists of a string of bases, each base being one of the four types A, C, G and T
ENCODED DATA FILE/DATA OBJECT—a data file (for file-based storage systems) or a data object (for object-based storage systems) containing compressed NGS data, generating by compressing a native NGS data file or data object.
FASTQ—a standard file format for machine output files.
FIELD—a consecutive sequence of data values within a native NGS data file or data object, for which all values represent the same type of information. E.g., a read field contains a string of values that represent NA bases identified by a sequencing machine.
MACHINE OUTPUT FILE—a file containing the digital data that is generated by a sequencing operation of a sequencing machine. A machine output file may be generated by the sequencing machine, or may be the result of a format translation performed on the direct output of the machine. E.g., sequencing machines by Illumina Inc. of San Diego, Calif., generate machine output files in a BCL format, and these files may be translated to machine output files in the FASTQ format
NA—a nucleic acid, either deoxyribonucleic acid (DNA) or ribonucleic acid RNA
NATIVE NGS DATA FILE/DATA OBJECT—a data file or data object containing genomics data in a standard NGS format. The data in the file may be uncompressed, such as inter alia for FASTQ and SAM formats, or compressed, such as inter alia for BAM formats.
PORTION—a part of a file that is compressed as an atomic unit, so that the portion along can be decompressed to read the native NGS data.
QUALITY SCORE—a data value produced by a sequencing machine that represents the machine's estimate of the probability of error of a base. The correspondence between a quality score and a base in a read depends on the file format.
READ—a field in a machine output file and in an alignment file that contains the NA bases identified by the sequencing machine.
REFERENCE NA—an NA of a pre-specified composition that is used by an aligner to determine the location of reads and any differences. The reference NA is provided to the aligner and reported in the alignment file. E.g., human DNA may be aligned using a reference human DNA.
SAM—a standard file format for alignment files
SECTION—a part of a machine output file or alignment file that includes an ordered set of fields of a specific type. Thus, a section of a machine output file in the FASTQ format includes a tag field, a read field and a quality score field. An alignment file in the BAM and SAM format includes a header section followed by one or more alignment sections.
SLICE—a logical part of a machine output file or alignment file that contains all the fields of a specific type. Thus a machine output file may be logically partitioned into a slice that contains the tags, a slice that contains the reads, and a slice that contains the quality scores.
TAG—a field type of a machine output file that contains information about the sequencing machine and on the sequencing process that produces the machine output file and the section that includes the tag.

### LIST OF APPENDICES

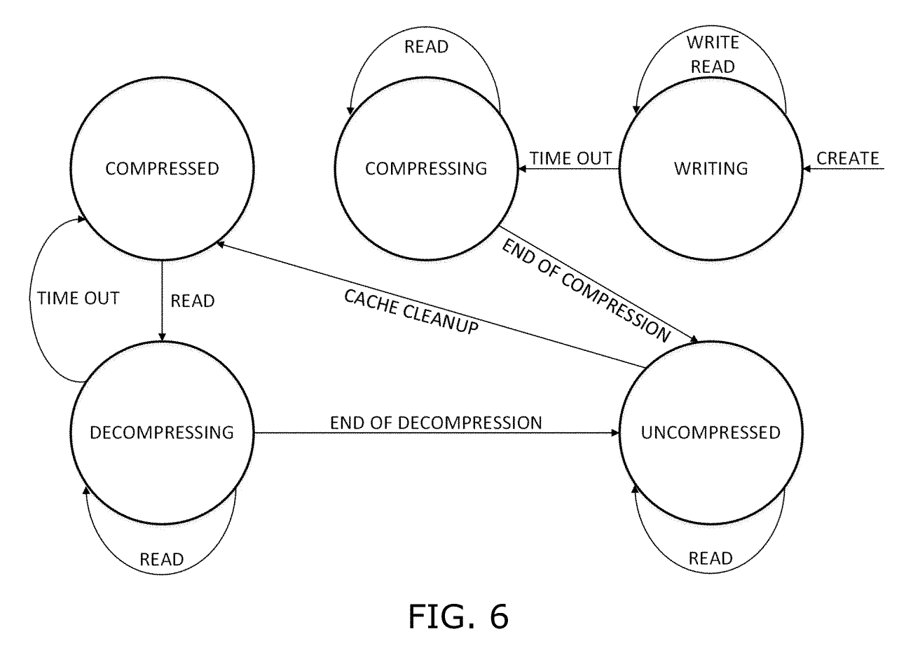

APPENDIX A is a pseudo-code listing for the processing threads of FIG. 5, in accordance with an embodiment of the present invention.

### DETAILED DESCRIPTION

In accordance with embodiments of the present invention, systems and methods are provided for storage, transfer and compression of next generation sequencing (NGS) data.

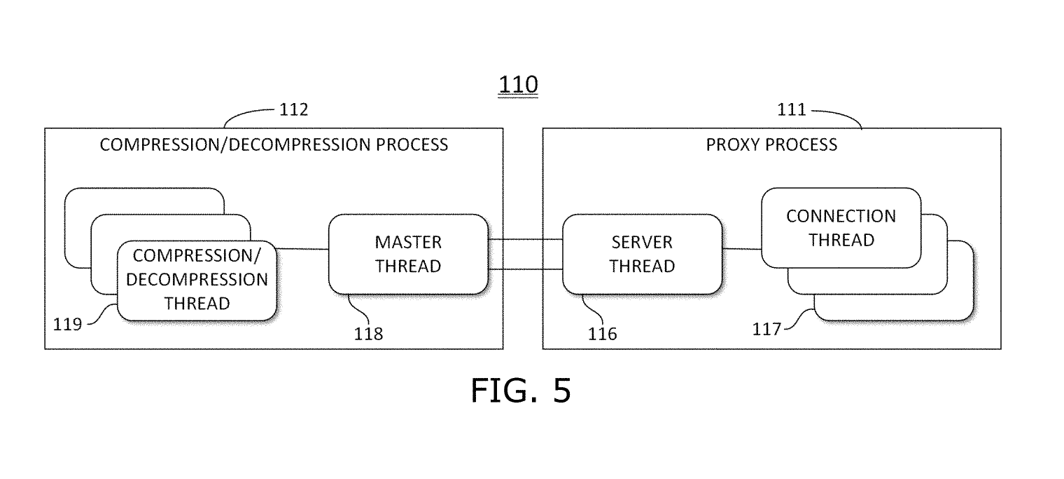

Reference is made to FIG. 4, which is a simplified block diagram of a system for storage, transfer and compression of next generation sequencing (NGS) data, in accordance with an embodiment of the present invention. The system of FIG. 4 includes four major components; namely, a computer appliance 100, one or more client computers 200, a storage system 300, and a cache system 400. Appliance 100 serves as an intermediary between client computer 200 and storage system 300. Client computer 200 includes a processor 210 that runs an NGS application 220 that processed native NGS data. Storage system 300 includes a processor 310 that manages a data storage 320. Storage system 300 may be a network-attached storage (NAS), and may be a file-based system that uses a file access protocol and stores encoded data files, or an object-based system that uses an object store protocol and stores encoded data objects, or such other storage system in use today or in the future for storing NGS data. Cache system 400 includes a processor 410 that manages an NGS data cache 420.

Use of cache enables “storage tiering”. If cache 400 has faster access time than storage system 300, e.g., through use of solid-state disk drives, then reads from cache 400 are faster than reads from storage system 300 due to their not requiring decompression, and due to the fast storage medium.

Although not shown in FIG. 4, each of computer appliance 100, client computer 200, storage system 300, and cache system 400 includes one or more memory modules, data buses and transmitters/receivers, as required for performing the various operations described hereinbelow, and as required for communicating with one another.

Appliance 100 includes a front-end interface 120 communicating with client computer 200 using a first storage access protocol, such as inter alia a file access protocol or an object store protocol. In some embodiments of the present invention, front-end interface 120 is a network file system (NFS) interface. Appliance 100 also includes a back-end interface 130 communicating with storage system 300 using a second storage access protocol, such as inter alia a file access protocol or an object store protocol. In some embodiments of the present invention, back-end interface 130 is a Swift object store interface. The first and second storage access protocols may be the same or different protocols.

Appliance 100 also includes a compressor 140 and a decompressor 150. Appliance 100 provides several services to client computer 100, including customized compression of NGS data in a manner that is transparent to NGS application 220. Specifically, using appliance 100 as an intermediary, NGS application 220 processes native, NGS data, whereas storage system 300 stores encoded NGS data files or data objects.

Compressor 140 is programmed to receive native NGS data from application 220 via front-end interface 120, to add a compressed form of the native NGS data into a portion of an encoded data file or data object, and to store the portion of the encoded data file or data object in storage system 300 via back-end interface 130. Decompressor 150 is programmed to receive a portion of an encoded data file or data object from storage system 300 via back-end interface 130, to decompress the portion of the encoded data file or data object to generate therefrom native NGS data, and to transmit the native NGS data to client 200 via front-end interface 120, for use by application 220.

It will be appreciated by those skilled in the art that there are many variations to the architecture of FIG. 4, which are alternative embodiments of the subject invention. Thus, NGS data cache 420 may be resident in appliance 100, in client computer 200 or in storage system 300, instead of or in addition to being resident in a separate cache system 400. Appliance 100, client computer 200, storage system 300 and cache system 400 may be separate computing systems, or parts of one or more same computer systems, in which case two or more of processors 110, 210, 310 and 410 may be the same processor. E.g., appliance 100 may be part of client computer 200, or part of storage system 300, instead of being a separate computer.

In a cloud-based embodiment of the present invention, appliance 100 is a virtual appliance that runs in a cloud environment such as that provided by Amazon Technologies, Inc. of Seattle, Wash.; client computer 200 is a virtual computer such as that provided as an Elastic Compute Cloud (EC2) instance by Amazon; storage system 300 is a cloud storage system such as Simple Storage Service (S3) provided by Amazon; and cache 400 is a cloud-based storage system such as an Elastic Block Storage (EBS) service provided by Amazon. In a cloud-based embodiment of the present invention, front-end interface 120 communicating with client computer 200 over a virtual private cloud (VPC) local area network (LAN) using a first storage access protocol, such as inter alia a file access protocol or an object store protocol. In some embodiments of the present invention, front-end interface 120 is a Network File System (NFS) interface. In a cloud-based embodiment of the present invention, back-end interface 130 communicates with cloud storage system 300 using a second storage access protocol. In some embodiments of the present invention, back-end interface 130 is an Amazon S3 interface. Appliance 100 presents virtual computer 200 with an NFS server interface that allows unmodified Portable Operating System Interface (POSIX)-compliant application 220 to read and write native NGS files.

In accordance with an embodiment of the present invention, appliance 100 is a compressed file server that manages a FASTQ-optimized and BAM-optimized, compressed file system on any 3rd party NAS 300.

In accordance with an embodiment of the present invention, appliance 100 operates as a ‘bump-in-the-wire’ on the file services connection between user applications 220 and NAS 300. Appliance 100 may use an NFS back-end interface 130 to manage a compressed file system using dedicated storage capacity on the NAS, and an NFS front end interface 120 that provides file system services to applications. FASTQ files and BAM files are stored on NAS 300 in compressed format, while user applications read and write the same files in their native format, with appliance 100 performing on-the-fly compression and de-compression. File types other than FASTQ and BAM pass through appliance 100 in their native, unmodified format.

Embodiments of the present invention support NFS version 3. MOUNT procedures are supported over UDP and TCP, and other NFS procedures are supported over TCP.

Provisioning appliance 100 involves (i) configuring the NAS to export to appliance 100 a sub-tree of the file system that is managed by appliance 100; and (ii) configuring client computer 200 to mount the same sub-tree from appliance 100.

The NAS-resident compressed file system is POSIX compliant, and may be architected, provisioned, backed-up and otherwise managed using existing generic tools and best-practices.

Appliance 100 acts as a remote procedure call (RPC) proxy for NFS traffic associated with client computer access to the relevant part of the NAS. Front-end interface 120 terminates NFS-carrying TCP connections, or receives the associated UDP packets from client computer 200. Appliance 100 parses RPC calls and NFS commands to determine which NFS commands may be passed through essentially unmodified and which involve FASTQ or BAM file operations and therefore require modification. Modified or unmodified NFS commands are then forwarded to the NAS 300 through back-end interface 130. The same general procedure is applied to NFS replies in the reverse direction.

Most NFS commands, such as inter alia file operations on non-FASTQ and non-BAM files, pass through appliance 100 with no modification to any of the NFS fields. Changes made to such commands include: (i) at the RPC level, calls are renumbered by overwriting the XID field, with the original values restored in the replies; and (ii) calls to and replies from NAS 300 are carried over a different TCP connection or UDP packet, which have appliance 100 as their source.

Some NFS commands require additional NFS-level changes to the command or to the reply. E.g., a READDIR reply reporting on a directory that contains compressed FASTQ or BAM files is edited to show uncompressed files.

FASTQ or BAM file read or write requests trigger operation of compressor 140 and decompressor 150, which use back-end interface 130 to access NAS 300 in order to compress or decompress the relevant file before servicing the request, as further explained hereinbelow.

### Storage-Based Operations

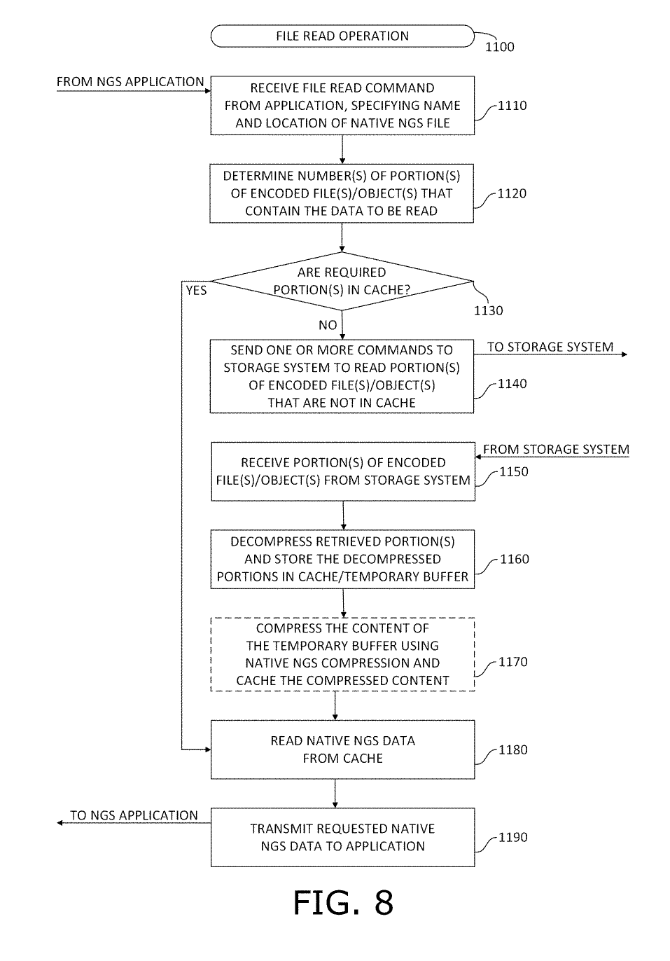

In order that appliance 100 be transparent to NGS application 220, appliance 100 must receive native NGS file commands from application 220, and issue commands to storage system 300, adapting them to account for storage system 300 storing encoded files and not native NGS files, receive responses from storage system 300, adapt them, and send native file responses to application 220. Details of adapting specific NGS commands are described hereinbelow with reference to FIGS. 7-26. It will be appreciate by those skilled in the art that for non-NGS file commands; i.e., commands related to files other than native NGS files, appliance 100 merely acts as a pass-through between client 200 and storage system 300, with adaptation.

Front-end interface 120 intercepts NFS READ commands from a FASTQ or BAM file and queues them. Front-end interface 120 notifies compressor 140 and decompressor 150 of the FASTQ or BAM file that is being read, and indicates the range of data in the file that has been requested so far. Decompressor 150 uses back-end interface 130 to read the compressed FASTQ or BAM file, to decompress the data, and to write the result to a native-format FASTQ or BAM file that resides on cache 400 and is one-to-one associated with the compressed file. As decompression progresses, decompressor 150 periodically communicates to front-end interface 120 the range of data that has been decompressed thus far. As READ commands continue to arrive, front-end interface 120 updates decompressor 150 as to new data that is requested. In parallel, when uncompressed file data becomes available for serving queued commands, front-end interface 120 forwards these commands to cache 400 and relays the replies to client computer 200.

READ commands and replies relating to non-FASTQ and non-BAM files are passed transparently by appliance 100.

NFS CREATE and WRITE commands of a FASTQ or BAM file are relayed by front-end interface 120 to cache 400 as commands on a native-format FASTQ or BAM file that is one-to-one associated with the intended compressed file. The end of the file is detected by a time-out since the last WRITE command. On time-out, front-end interface 120 notifies compressor 140, which compresses the cached file to a stable, compressed file in storage system 300.

CREATE and WRITE commands and replies to and from non-FASTQ and non-BAM files are passed transparently by appliance 100.

Uncompressed FASTQ and BAM files—either the input to compressor 140 or the output of decompressor 150—are cached in their native format and used to service subsequent READ commands. Appliance 100 runs a cache management process that keeps the total size of cached files below a configurable limit by deleting least recently accessed files.

Reference is made to FIG. 5, which is a simplified block diagram of processes and threads run by processor 110 of appliance 100, in accordance with an embodiment of the present invention. Processor 110 runs two main processes, a proxy process 111 and a compression/decompression process 112.

Proxy process 111 runs a permanent server thread 116 that listens on the NFS server and mount ports. Server thread 116 creates a new connection thread 117 to handle each incoming client computer connection. Connection threads 117 implement the RPC proxy functions for their associated connections, including communication with client computer 200 and storage system 300 over the incoming and outgoing TCP connections, respectively.

When triggered by client computer NFS commands such as READ or WRITE, requests for file compression or decompression are sent from a connection thread 117, through server thread 116, to compression/decompression process 112.

Compression/decompression process 112 has a permanent master thread 118 that accepts, from server thread 116, requests for file compression and decompression. When receiving a compression or decompression request, master thread 118 creates a new compression/decompression thread 119 that performs compression or decompression of the file.

Within proxy process 111, server thread 116 and connection threads 117 use POSIX message queues to pass information related to operations on FASTQ and BAM files, such as inter alia read request data ranges and decompress progress reports.

Inter-process communication between proxy process 111 and compression/decompression process 112 is implemented by proprietary messages passed over Linux FIFOs. When a new FASTQ or BAM file compression or decompression process needs to be started, server thread 116 of proxy process 111 sends an appropriate message to master thread 118 of compression/decompression process 112, which creates a new compression/decompression thread 119 to perform the requested task. From that point on, messages related to compression or de-compression are exchanged directly between server thread 116 and the relevant compression/decompression thread 119.

Server thread 116 consolidates READ requests on a per-file basis and communicates the result to a FIFO read by the relevant compression/decompression thread 119. (In distinction, file WRITE only involves one initial request, which triggers creation of compression thread 119.) Indications such as READ progress and WRITE completion are communicated from compression/decompression thread 119 to the server thread's FIFO and from there to all connection threads 117 that have pending requests related to that file.

Appliance 100 creates and manages an NFS compliant, compressed file system stored on NAS 300 and cache 400. The compressed file system mirrors the directory structure of the original, uncompressed file system, using the original directory names. Non-FASTQ and non-BAM files are stored in the compressed file system at their original location, in their original name and in their original, unmodified format.

A FASTQ or BAM file is represented in the compressed file system by two files, as follows.
i. A cached FASTQ or BAM file, which has the same name and is located in the same directory as the original FASTQ or BAM file. This file serves as a cached copy of the original file for a period of time after compression or decompression. At other times, its length is truncated to zero, but it is not deleted. The cached FASTQ or BAM file is renamed and moved to reflect any such operation performed on the original FASTQ or BAM file. Optionally, appliance 100 may serve a file in one of a number of formats. E.g., a FASTQ file may be served in either a native format or a zip-compressed format. As another example, a BAM file may be served in the native format or in a format where zip blocks are compressed with zip level 0; i.e., uncompressed data within a zip archive. In such a case, the file is represented by a number of aliases; i.e., the file name with different extensions, without data duplication. When application 220 wants to read the file in a specific format, it specifies the corresponding file extension and appliance 100 decompresses and serves the file in the requested format.
ii. A compressed FASTQ file which is placed in a special directory, created when provisioning appliance 100. The file's name is a string representation of the hexadecimal value of the NFS handle of the cached FASTQ file. Since this name is a simple function of the permanent NFS file handle of the cached FASTQ file, the association between the two is not affected by rename or move operations on the latter.

Appliance 100 indexes files and directories based on their NFS file handle. This makes it possible for file and directory identification to be permanent throughout their lifetime, independent of name changes or moves.

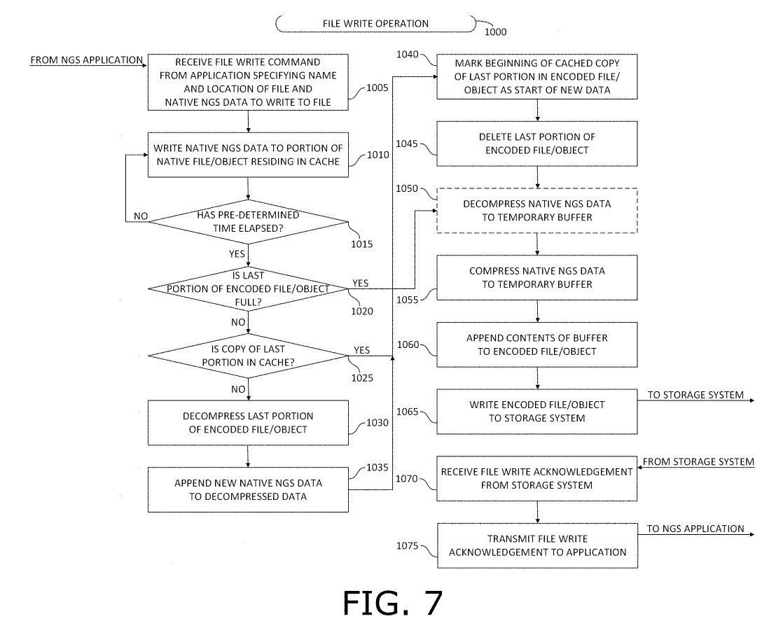

Each encoded FASTQ and BAM file has a state associated therewith, from among the five states ‘writing’, ‘compressing’, ‘compressed’, ‘decompressing’, ‘uncompressed’. Reference is made to FIG. 6, which is a state transition diagram for the five states of a cached FASTQ and BAM file, in accordance with an embodiment of the present invention.

A FASTQ and BAM table data structure is used to track the state and attributes of cached FASTQ and BAM files. Table lookup is done by the file's NFS handle, through a hash. The table stores the following file information:
Original uncompressed size.
Time of last modification and time of last modification of file attributes. It is noted that this information cannot be read from the attributes of the cached FASTQ or BAM file as maintained by the cache 400, since the cached FASTQ or BAM file is rewritten every time the file is decompressed.
File state.
Compressed size.
The ranges of data in the file that are currently uncompressed and available for reading.
Last access time, used for timing of operations such as compression following write as well as cache management.

Appliance 100 manages files and directories based on their NFS file handle. File and directory path names are useful for administrative purposes. To support these path names, appliance 100 maintains a tree data structure that mirrors the directory and file structure of the NAS-resident file system it manages. Each node in the tree contains the following information:
type, which is either file or directory;
name;
a pointer to the parent node in the tree;
for a directory, a pointer to the start of a linked list of child nodes; and
a pointer for a linked list of sibling nodes.

The tree data structure provides information for all files in the system, including non-FASTQ files. Appliance 100 maintains a look-up table data structure that maps an NFS file handle, through a hash, to a node in the tree data structure.

To maintain file system integrity across system reboots, a non-volatile copy of the FASTQ or BAM table is stored in a NAS-resident file. The table is loaded from the file at boot, and any changes to it during system operation are committed to stable storage as journal entries appended to the file. Following the next system boot, and once all journal entries have been incorporated into the memory-resident table, the updated table is written back to permanent storage as a new version of the file.

The tree data structure and associated look-up table are used for administrative purposes. As such, they are not kept in permanent storage. It is the responsibility of connection threads 117 to update the data structure as they process NFS commands such as LOOKUP and READDIR. Following system boot, an internal NFS client traverses the compressed file system tree, generating in the process NFS commands that, through processing by the respective connection thread 117, drive initial population of the tree.

Reference is made to APPENDIX A, which is a pseudo-code listing of thread processing for server thread 116 (lines 84-118), connection thread 117 (lines 1-83), master thread 118 (lines 119-130) and compression/decompression thread 119 (lines 131-150), in accordance with an embodiment of the present invention.

As indicated at line 5 of APPENDIX A, once created by server thread 116 to serve an NFS client computer connection, a connection thread 117 accepts inputs from (i) the two TCP sockets associated with client computer 200 and storage system 300 connections, and (ii) the message queue used to receive messages from server thread 116.

As indicated at lines 6 and 7 of APPENDIX A, RPC calls, carrying NFS commands, received from client computer 200 are renumbered by overwriting their XID field. As indicated at line 44 and 45 of APPENDIX A, the field is then restored to its original value in replies forwarded back to client computer 200. (Without renumbering, RPC calls arriving from different client computers that carry the same XID could be interpreted by the NFS server as retransmissions of the same call, since they arrive from the same IP address.)

Processing of NFS commands and replies received from client computer 200 and storage system 300 connection sockets, respectively, depends on the type of command and type of file addressed, as follows.

As indicated at lines 8-11 of APPENDIX A, for MOUNT commands, the path to the root of the file tree to be mounted is validated against the original file system export as configured into appliance 100. If correct, the command is forwarded to NAS 300. As indicated at lines 46-49 of APPENDIX A, The reply is forwarded to client 200 after recording the file handle of the root of the tree. The handle is used to build the tree data structure.

As indicated at lines 12-14 and 50-52 of APPENDIX A, general file system commands such as FSSTAT and FSINFO and the replies associated with them are passed unmodified by appliance 100.

For NFS commands addressing files, appliance 100 determines through the file name or file handle whether or not it is a FASTQ or BAM file. For commands that address the file by name, e.g., CREATE, the classification is based on the file name's suffix, ‘.fq’ or ‘.fastq’ or ‘bam’ vs. other. For commands that specify the file by handle, the file type is identified by searching the FASTQ or BAM table to determine whether or not the file is listed in it.

As indicated at lines 15-20 and 53-55 of APPENDIX A, commands addressing non-FASTQ or non-BAM files, and the replies associated with them, are passed unmodified by appliance 100. In the process, file and directory names specified by CREATE, RENAME, REMOVE, LOOKUP, READDIR or READDIRPLUS commands are used to update the tree data structure and associated look-up table.

As indicated at lines 21-32 and 56-69 of APPENDIX A, commands addressing directories or FASTQ or BAM files are processed and potentially modified by appliance 100 as follows.

GETATTR (lines 22 and 57 of APPENDIX A): When addressing a FASTQ or BAM file, the command is forwarded to NAS 300, which responds with the attributes of the cached FASTQ or BAM file. Appliance 100 modifies the reply to show: (i) the original uncompressed file size; and (ii) the true last-modified time stamp, disregarding decompression, which re-writes the cached FASTQ or BAM file.

SETATTR (lines 23 and 58 of APPENDIX A): Setting the file size attribute of a FASTQ or BAM file or any attribute of a compressed file are not permitted. Commands for other changes are forwarded to NAS 300 unmodified and, if reported in the reply as accepted, are forwarded to client 200 and used to update the FASTQ or BAM table.

LOOKUP (lines 24 and 59of APPENDIX A): The command is forwarded to NAS 300 and the reply back to client 200. The information in the reply is used to update the tree data structure.

ACCESS, READLINK, SYMLINK (lines 25-27 and 60-62 of APPENDIX A): The command and reply are passed unmodified.

MKDIR (lines 28 and 63 of APPENDIX A): The command and reply are passed unmodified. If the operation is successful, the information in the reply is used to add an entry to the tree data structure.

REMOVE (lines 29 and 64 of APPENDIX A): The command and reply are passed unmodified. If the operation is successful, a remove message is sent to the server thread, serving as a trigger to cleanup.

RMDIR (lines 30 and 65 of APPENDIX A): The command and reply are passed unmodified. If the operation is successful, the associated entry is removed from the tree data structure.

RENAME (lines 31 and 66 of APPENDIX A): The command and reply are passed unmodified. If the operation is successful, the information in the reply is used to update the tree data structure.

READDIR, READDIRPLUS (lines 32, 33 and 67-69 of APPENDIX A): The command is passed unmodified. The reply is modified (i) to show access permissions of 000 for compressed files; and (ii) to show the original uncompressed size and true last-modified timestamp for FASTQ or BAM files.

As indicated at lines 34-43 and 70-76 of APPENDIX A, NFS commands related to the creation, writing to and reading from FASTQ or BAM files involve the following process.

CREATE (lines 34, 70 ad 71 of APPENDIX A): Appliance 100 tracks the amount of free space available in cache 400 for uncompressed cached files. If no space is available the CREATE command is rejected with an out-of-space error code. Otherwise, the command and reply are passed unmodified. If the operation is successful, an entry is added to each of the data structures and a CREATE message is sent to server thread 116.

WRITE, COMMIT (lines 35, 36, 72 and 73 of APPENDIX A): These commands are accepted only when the file is in the ‘writing’ state. In the ‘writing’ state, the commands and replies are passed unmodified and the last-modified timestamp field in the FASTQ or BAM table is updated to support start of compression on timeout.

READ (lines 37-43 of APPENDIX A): When the file is in the ‘writing’, ‘compressing’ or ‘uncompressed’ state, READ commands are passed unmodified. Otherwise, when the file is in the ‘compressed’ or ‘decompressing’ state, connection thread 117 compares the range of file data that is requested by the READ command with the range of data that is available for reading as appears in the FASTQ or BAM table entry for the file. If the requested data is available, the command is forwarded to NAS 300. Otherwise, the command is queued and a decompress message for the file is sent to server thread 116, specifying the new data range requested for reading from the file.

Connection thread 117 receives, through the POSIX message queue, reports from server thread 116 on the progress of file decompression. Upon receiving such a report, connection thread 117 scans the READ command queue and releases for forwarding to the NFS server requests for data that has become available.

As indicated at line 74 of APPENDIX A, READ replies are forwarded back to client 200. The last-accessed time stamp in the FASTQ or BAM table is updated with the access time to support cache management.

As indicated at line 80 of APPENDIX A, connection thread 117 also accepts ABORT messages from server thread 116, signaling that the file being read has been deleted by another connection thread 117. When an ABORT message is received, connection thread 117 replies to all queued READ commands with an error reply.

Server thread 116 maintains four lists of files that are currently in one of the four transitional states: ‘writing’, ‘compressing’, ‘decompressing’ and ‘uncompressed’. (The stable state is ‘compressed’.) In the ‘decompressing’ list, the entry for each file includes the list of connection threads 117, identified by their message queues, which are waiting to read data from the file.

Server thread 116 receives inputs from (i) the message queue that accepts messages from connection threads 117, and (ii) the FIFO that receives messages from threads 119 of the compression/decompression process 112.

As indicated at lines 89-100 of APPENDIX A, server thread 116 accepts three types of messages from connection threads 117, as follows.
CREATE (line 91 of APPENDIX A): The state of the file in the FASTQ or BAM table is changed to ‘writing’ and the file is added to the ‘writing’ list.
DECOMPRESS (lines 92-97 of APPENDIX A): If the file is not yet in the ‘decompressing’ state, i.e., if the message was triggered by the first READ command since the file was created or removed from the cache, then the cache management process is executed. If there is no room in cache 400, old files are deleted. The state of the file is changed to ‘decompressing’ and the file is added to the ‘decompressing’ list. Then, and for every following DECOMPRESS request for the file, a DECOMPRESS request is sent to compression/decompression process 112 to update it as to the data range in the file that is requested for reading. REMOVE (lines 98-100 of APPENDIX A): An ABORT message is sent to compression/decompression thread 119 to stop file compression or decompression. An ABORT message is also sent to all connection threads 117 that are currently reading from the file. The file entry is then removed from the data structures.

As indicated at lines 101-107 of APPENDIX A, while the ‘writing’ list is not empty, server thread 116 uses an idle timer to periodically scan the list and determine for which files, if any, a suitable time period has elapsed since the last WRITE, and compression should therefore start. For each such file, a COMPRESS request is sent to compression/decompression process 112, and the file is moved to the ‘compressing’ list.

Server thread 116 accepts four types of messages from compression/decompression process 112 through the FIFO, as follows.
COMPRESS START report (line 109 of APPENDIX A): Compression/decompression process 112 responds to a COMPRESS request with a COMPRESS START report, which includes the name of the input FIFO of the compression/decompression thread 119 performing the compression. This FIFO is the address of ABORT messages related to the file.
COMPRESS END report (line 110 of APPENDIX A): The file is moved to the ‘compressed’ list.
DECOMPRESS START (line 111 of APPENDIX A): Compression/decompression process 112 responds to a DECOMPRESS request with a DECOMPRESS START report, which includes the name of the input FIFO of the compression/decompression thread 119 performing the decompression. This FIFO is the address of further DECOMPRESS requests and ABORT messages related to the file.
DECOMPRESS report (lines 112-114 of APPENDIX A): the FASTQ or BAM table is updated with new data that is available for reading and this information is shared, through progress report messages, with all connection threads 117 that are reading from the file. When the DECOMPRESS report indicates that the end of the file has been reached, the file is moved to the ‘uncompressed’ list.

As indicated at line 123 of APPENDIX A, master thread 118 of compression/decompression process 112 waits for messages arriving at its input FIFO from server thread 116. As indicated at lines 124-126 of APPENDIX A, two types of messages are accepted; namely, COMPRESS request and DECOMPRESS request. A COMPRESS request specifies the NFS file handle of the cached FASTQ or BAM file. A DECOMPRESS request specifies the full pathname of the compressed FASTQ file as well as the range of data that should be decompressed in the file.

As indicated at lines 125-127 of APPENDIX A, when a COMPRESS or DECOMPRESS request is received, master thread 118 creates a compression/decompression thread 119 to perform compression/decompression of the file. The newly created thread 119 is provided with an identity, handle or name, of the file to be processed as well as, in the case of decompression, the range of data that should be decompressed in the file.

As indicated at lines 134-140 of APPENDIX A, a compression/decompression thread 119 that was created for compression of a file creates the compressed file and then sends a COMPRESS START report to server thread 116 of proxy process 111. The message includes the name of the thread's input FIFO. When the thread 119 completes compression of the file, it sends a COMPRESS END report to server thread 116.

As indicated at lines 141-149 of APPENDIX A, a compression/decompression thread 119 that was created for decompression of a file sends a DECOMPRESS START report to server thread 116 of proxy process 111. The message includes the name of the thread's input FIFO. In the course of decompression, the compression/decompression thread 119 sends periodic DECOMPRESS reports to server thread 116, reporting on new file data that has been decompressed and is therefore available for reading. A flag in the report indicates when thread 119 has reached the end of the file.

During decompression, compression/decompression thread 119 accepts from server thread 116 DECOMPRESS requests that specify more data to decompress.

Reference is made to FIG. 7, which is a simplified flowchart of a method 1000 for performing a FILE WRITE operation, performed by an NGS storage, transfer and compression system, such as inter alia the system of FIG. 4, in accordance with an embodiment of the present invention. Method 1000 performs sequential write to a file; namely, writing information that is appended to the end of the file. When an NGS application writes data to a file, appliance 100 first writes the data to a portion of a native NGS version of the file that resides in a cache.

At operation 1005, the system receives a FILE WRITE command from an NGS application, such as inter alia NGS application 220 of FIG. 4, specifying a name and location of a file in a storage system, such as inter alia storage system 300 of FIG. 4, and specifying native NGS data to write to the file. Generically, for a file access protocol the FILE WRITE command is of the form
null fileWrite(name fileName, location directoryLocation, NGS Data nativeNGSData).
   At operation 1010 the system writes the native NGS data to a portion of a native data file or data object residing in a cache, such as inter alia cache 400 of FIG. 4. The system waits until the pre-determined time since a previous portion of data was written to the file, and at decision 1015 the system decides whether or not the pre-determined time has elapsed. If not, the method returns to operation 1005 to receive addition data for writing. Otherwise, if the pre-determined time has elapsed, then at decision 1020 the system decides whether or not the last portion of the encoded data file or data object is full. If not, then at decision 1025 the system decides whether or not a copy of the last portion of the encoded file reside in the cache. If not, then at operation 1030 the system decompresses the last portion of the encoded data file or data object.

At operation 1035 the system adds the native NGS data specified at operation 1005 to the thus-decompressed last portion. At operation 1040 the system marks the beginning of the last portion of the cached copy as the start of new data. At operation 1045 the system deletes the last portion of the encoded file or data object.

At operation 1050 the system decompressed the native NGS data that was received at operation 1005. Operation 1050 is optional, and is only performed if the native NGS data is in a native format that is compressed, such as the BAM format, and not for native formats that are uncompressed, such as FASTQ. For BAM files, operation 1050 decompresses the ZIP block levels of the native files. At operation 1055 the system compresses the decompressed portion to a temporary buffer. At operation 1060 the system appends the contents of the buffer to the encoded data file or data object in the cache. At operation 1065 the system writes the encoded data file or data object in the cache to the storage system. At operation 1070 the system receives an acknowledgement from the storage system. At operation 1075 the system sends a file write acknowledgement to the NGS application.

If, at decision 1020, the system decides that the last portion of the encoded data file or data object is full, then processing advances directly to operation 1050. If, at decision 1025, the system decides that a copy of the last portion of the encoded file resides in the cache, then processing advances directly to operation 1040.

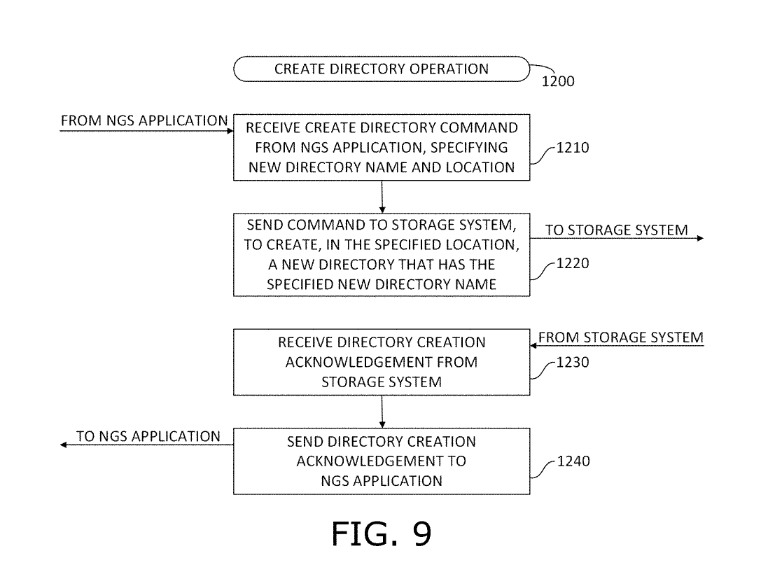

Reference is made to FIG. 8, which is a simplified flowchart of a method 1100 for performing a READ operation, performed by an NGS storage, transfer and compression system, such as inter alia the system of FIG. 4, in accordance with an embodiment of the present invention. At operation 1110 the system receives a READ command from an NGS application, to read data from a file specified by name and location in a storage system. Generically, for a file access protocol the FILE READ command is of the form
NGSData fileRead(name fileName, location directoryLocation).
   At operation 1120 the system determines the number(s) of portion(s) of encoded file(s) that contain the data to be read. It will be appreciated that in some embodiments of the present invention, a native NGS file may correspond to more than one encoded file. It will be appreciated that in some embodiments of the present invention, a native NGS file may correspond to more than one encoded file. At decision 1130 the system determines if all of the required portion(s) are in a cache, such as cache system 400 of FIG. 4. If not, then at operation 1140 the system sends one or more commands to the storage system, to read those portion(s) of the encoded file(s) that are not in the cache. At operation 1150 the system receives the requested portion(s) of the encoded file(s). At operation 1160 the system decompressed the portion(s) received at operation 1150, and caches the decompression portion(s). If the native NGS data is in a native format that is compressed, such as the BAM format, then instead of caching the decompression portion(s), they are stored in a temporary buffer. Then, at operation 1170 the system compresses the content of the temporary buffer using the native NGS compression. Operation 1170 is shown as optional, since it only needs to be performed when the native NGS format is a compressed format, such as the BAM format, and not for uncompressed formats such as the FASTQ format. For BAM files, operation 1170 compresses ZIP block levels of the temporary buffer.

At this stage all required portion(s) are in the cache. If the system determines at decision 1130 that all of the required portion(s) are in cache, then the method advances directly to operation 1180. At operation 1180 the system reads the requested native NGS data from the cache. At operation 1190 the system sends the requested native NGS data to the NGS application.

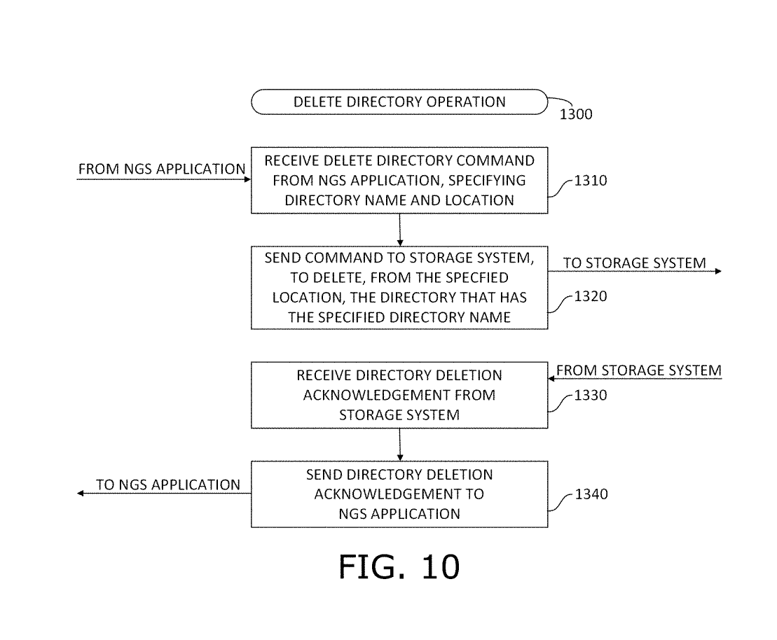

Reference is made to FIG. 9, which is a simplified flowchart of a method 1200 for performing a CREATE DIRECTORY operation, performed by an NGS storage, transfer and compression system, such as inter alia the system of FIG. 4, in accordance with an embodiment of the present invention. At operation 1210, the system receives a CREATE DIRECTORY command from an NGS application, such as inter alia NGS application 220 of FIG. 4, the command specifying a name and a location for a new directory to be created in a storage system. Generically, for a file access protocol the CREATE DIRECTORY command is of the form
null createDirectory(name directoryName, location directoryLocation).
   At operation 1220, the system sends a command to the storage system to create, in the specified location, a new directory that has the specified name. At operation 1230 the system receives a directory creation acknowledgement from the storage system. At operation 1240 the system sends a directory creation acknowledgement to the NGS application.

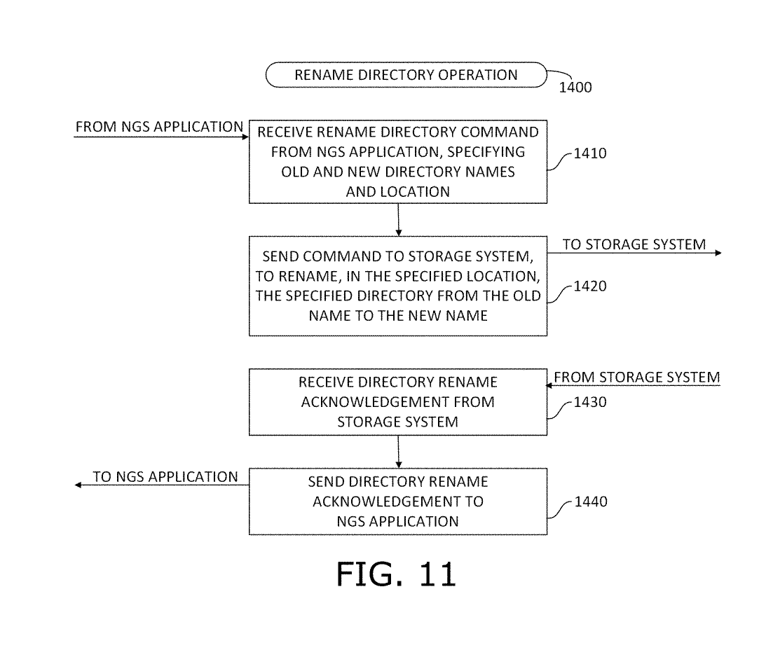

Reference is made to FIG. 10, which is a simplified flowchart of a method 1300 for performing a DELETE DIRECTORY operation, performed by an NGS storage, transfer and compression system, such as inter alia the system of FIG. 4, in accordance with an embodiment of the present invention. At operation 1310 the system receives a DELETE DIRECTORY command from an NGS application, such as inter alia NGS application 220 of FIG. 4, to delete a directory from a storage system, the command including a specified name and location of the directory. Generically, for a file access protocol the DELETE DIRECTORY command is of the form
null deleteDirectory(name directoryName, location directoryLocation).
   At operation 1320 the system sends a command to the storage system, to delete, from the specified location, the directory that has the specified name. At operation 1330 the system receives a directory deletion acknowledgement from the storage system. At operation 1340 the system sends a directory deletion acknowledgement to the NGS application.

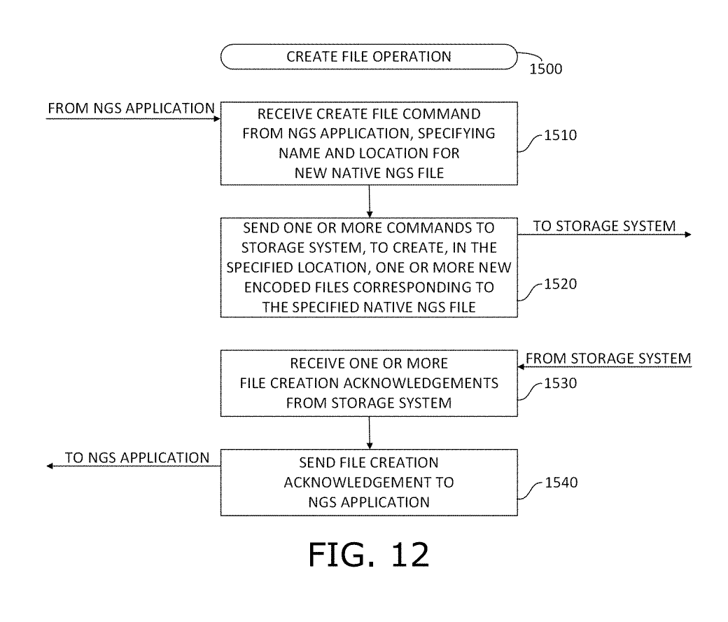

Reference is made to FIG. 11, which is a simplified flowchart of a method 1400 for performing a RENAME DIRECTORY operation, performed by an NGS storage, transfer and compression system, such as inter alia the system of FIG. 4, in accordance with an embodiment of the present invention. At operation 1410 the system receives a RENAME DIRECTORY command from an NGS application, such as inter alia NGS application 220 of FIG. 4, to rename a directory in the storage system, the command specifying the old name of the directory, the new name for the directory, and the location of the directory. Generically, for a file access protocol the RENAME DIRECTORY command is of the form
null renameDirectory(name oldDirectoryName, name newDirectoryName, location directoryLocation)
   At operation 1420 the system sends a command to the storage system to rename, in the specified location, the specified directory from the old name to the new name. At operation 1430 the system receives a directory rename acknowledgement from the storage system. At operation 1440 the system sends a directory rename acknowledgement to the NGS application.

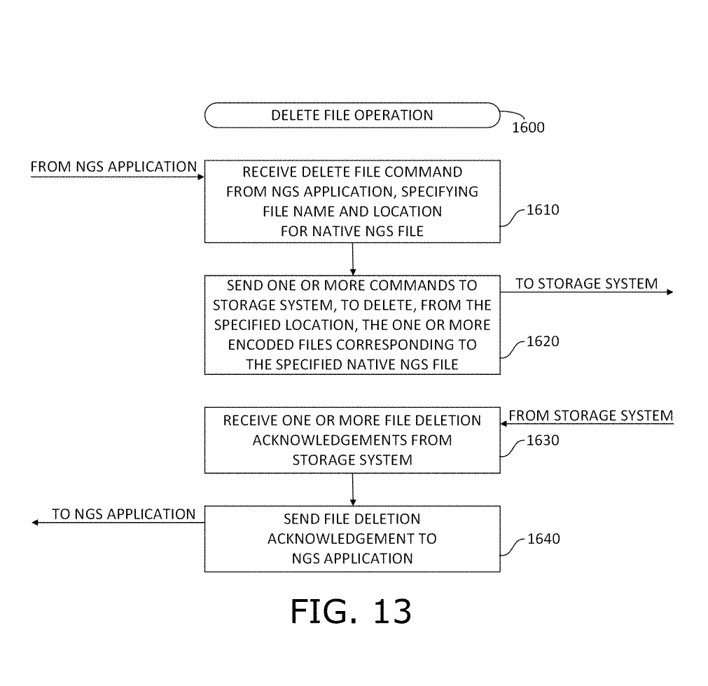

Reference is made to FIG. 12, which is a simplified flowchart of a method 1500 for performing a CREATE FILE operation, performed by an NGS storage, transfer and compression system, such as inter alia the system of FIG. 4, in accordance with an embodiment of the present invention. At operation 1510 the system receives a CREATE FILE command from an NGS application, such as inter alia NGS application 220 of FIG. 4, specifying a name and location for a new native NGS file to be created in a storage system. Generically, for a file access protocol the CREATE FILE command is of the form
null createFile(name fileName, location directoryLocation).
   At operation 1520 the system sends one or more commands to the storage system to create, in the specified location, one or more new encoded files corresponding to the specified native NGS file. It will be appreciated that in some embodiments of the present invention, a native NGS file may correspond to more than one encoded file. At operation 1530 the system receives one or more file creation acknowledgements from the storage system. At operation 1540 the system sends a file creation acknowledgement to the NGS application.

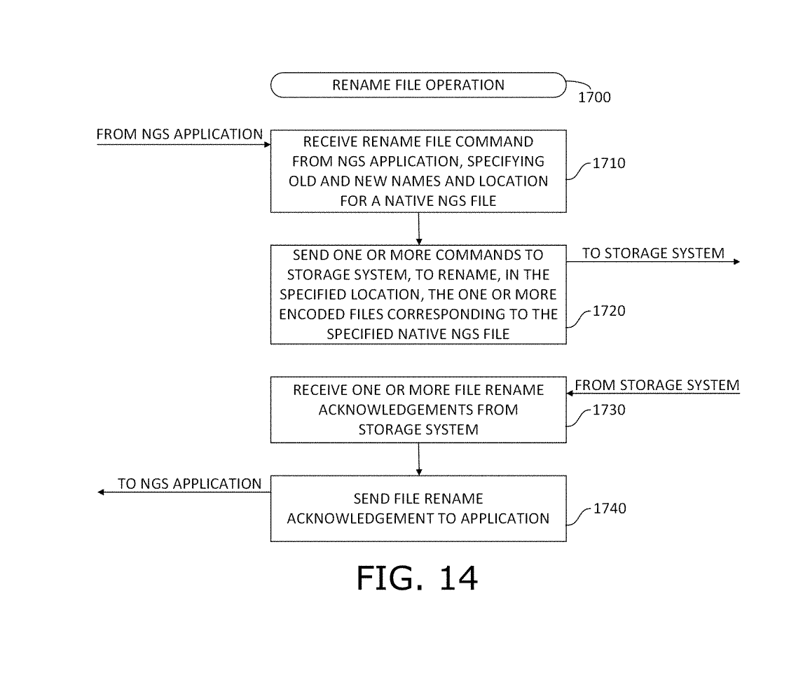

Reference is made to FIG. 13, which is a simplified flowchart of a method 1600 for performing a DELETE FILE operation, performed by an NGS storage, transfer and compression system, such as inter alia the system of FIG. 4, in accordance with an embodiment of the present invention. At operation 1610 the system receives a DELETE FILE command from an NGS application, such as inter alia NGS application 220 of FIG. 4, specifying a name and location of a native NGS file to be deleted from a storage system. Generically, for a file access protocol the DELETE FILE command is of the form
null deleteFile(name fileName, location directoryLocation).
   At operation 1620 the system sends one or more commands to the storage system, to delete, from the specified location, one or more encoded files corresponding to the specified native NGS file. It will be appreciated that in some embodiments of the present invention, a native NGS file may correspond to more than one encoded file. At operation 1630 the system receives one or more file deletion acknowledgements from the storage system. At operation 1640 the system sends a file deletion acknowledgement to the NGS application.

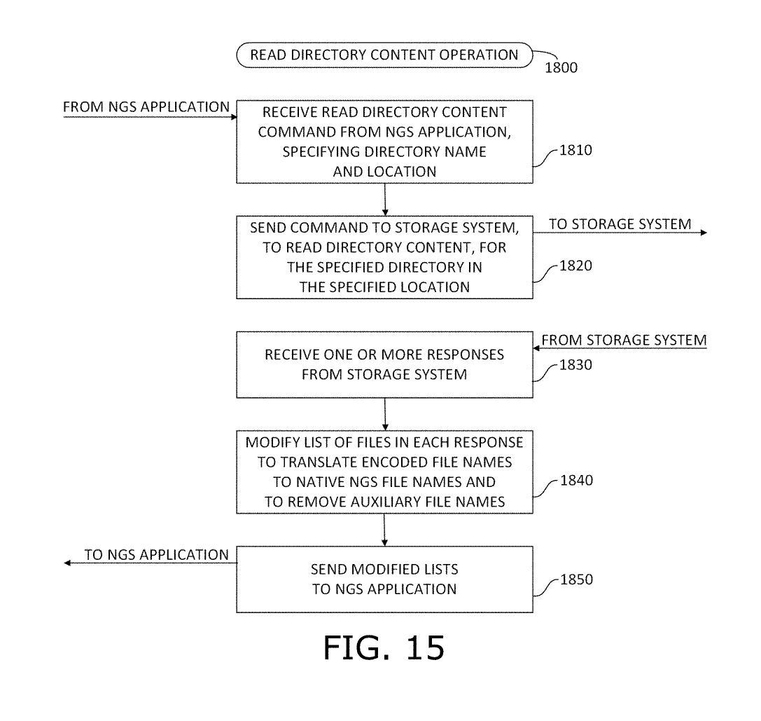

Reference is made to FIG. 14, which is a simplified flowchart of a method 1700 for performing a RENAME FILE operation, performed by an NGS storage, transfer and compression system, such as inter alia the system of FIG. 4, in accordance with an embodiment of the present invention. At operation 1710 the system receives a RENAME FILE command from an NGS application, such as inter alia NGS application 220 of FIG. 4, specifying and old name of, a new name for, and a location of a native NGS file to be renamed in a storage system. Generically, for a file access protocol the RENAME FILE command is of the form
null renameFile(name oldFileName, name newFileName, location directoryLocation).
   At operation 1720 the system sends one or more file command to the storage system to rename, in the specified location, one or more encoded files corresponding to the specified native NGS file. It will be appreciated that in some embodiments of the present invention, a native NGS file may correspond to more than one encoded file. At operation 1730 the system receives one or more file rename acknowledgements from the storage system. At operation 1740 the system sends a file rename acknowledgement to the NGS application.

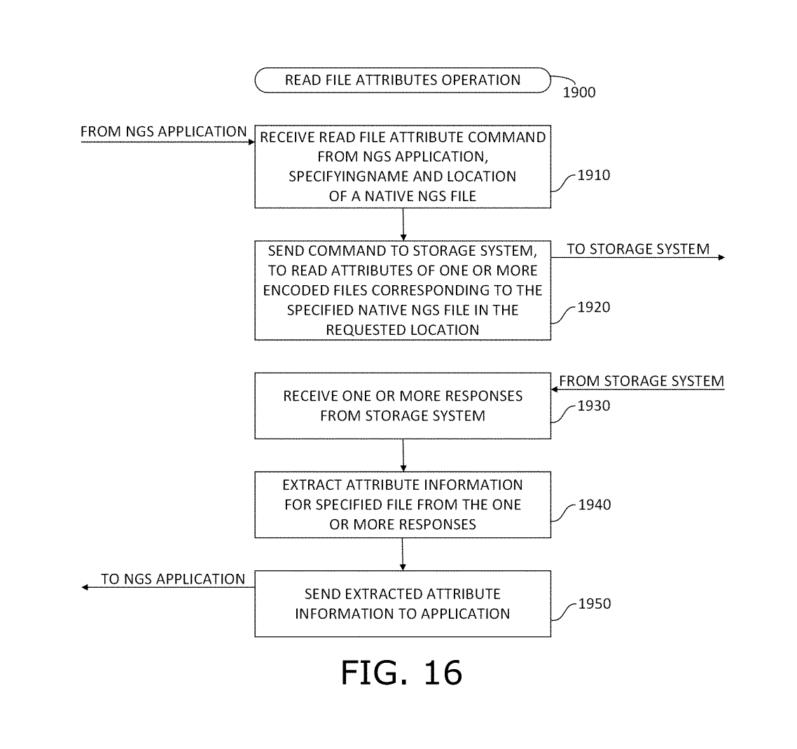

Reference is made to FIG. 15, which is a simplified flowchart of a method 1800 for performing a READ DIRECTORY CONTENT operation, performed by an NGS storage, transfer and compression system, in accordance with an embodiment of the present invention. At operation 1810 the system receives a READ DIRECTORY CONTENT command from an NGS application, such as inter alia NGS application 220 of FIG. 4, specifying a name and location of a directory in a storage system. Generically, for a file access protocol the READ DIRECTORY CONTENT command is of the form
list readDirectoryContent(name directoryName, location directoryLocation).
   At operation 1820 the system sends a command to the storage system to read content of the specified directory in the specified location. At operation 1830 the system receives one or more responses from the storage system, each response being a list of encoded files. At operation 1840 the system modifies the list of files in each response by translating encoded file names to native NGS file names, and by removing auxiliary encoded file names, for auxiliary encoded files that were generated by an NGS data compressor such as compressor 140 of FIG. 4. When a file is offered in more than one format, the system also duplicates the file entry to show one entry for each offered format (as distinguished by the file extension). At operation 1850 the system sends the thus-modified lists of files to the NGS application.

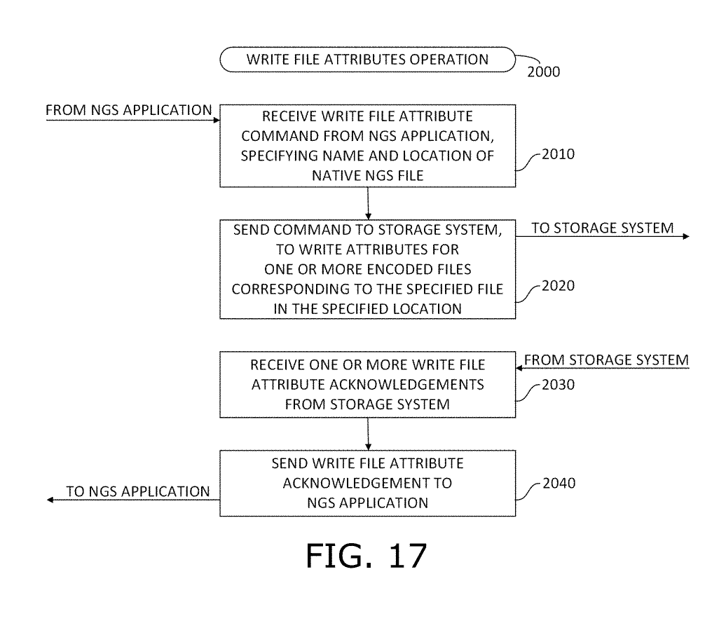

Reference is made to FIG. 16, which is a simplified flowchart of a method 1900 for performing a READ FILE ATTRIBUTES operation, performed by an NGS storage, transfer and compression system, in accordance with an embodiment of the present invention. At operation 1910 the system receives a READ FILE ATTRIBUTES command from an NGS application, such as inter alia NGS application 220 of FIG. 4, specifying a name and location of a native NGS file in a storage system. Generically, for a file access protocol the READ FILE ATTRIBUTES command is of the form
fileAttributes readFileAttributes(name fileName, location directoryLocation).
   At operation 1920 the system sends one or more commands to the storage system, to read attributes of one or more encoded files corresponding to the specified native NGS file, in the specified directory. It will be appreciated that in some embodiments of the present invention, a native NGS file may correspond to more than one encoded file. At operation 1930 the system receives one or more responses from the storage system. At operation 1940 the system extracts attributes of the specified native NGS file from the one or more responses received at operation 1930. At operation 1950 the system sends file attribute information to the NGS application.

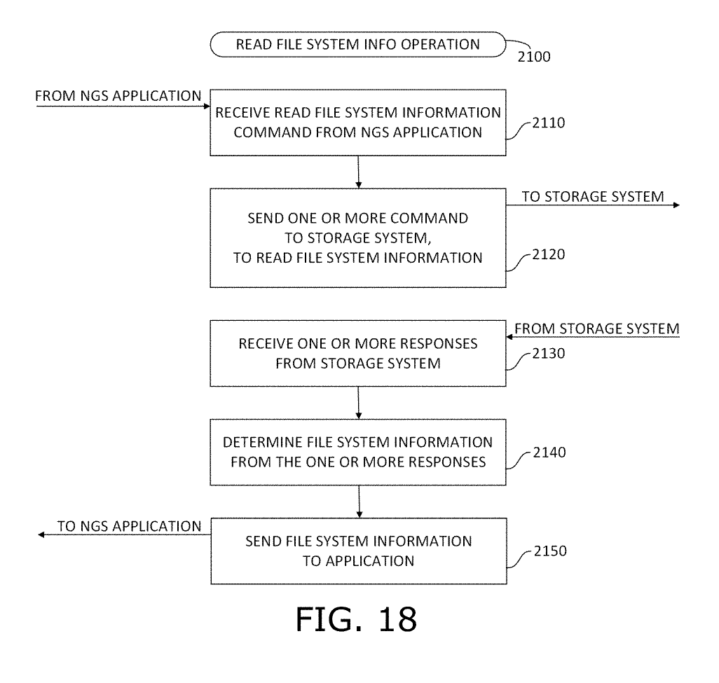

Reference is made to FIG. 17, which is a simplified flowchart of a method 2000 for performing a WRITE FILE ATTRIBUTES operation, performed by an NGS storage, transfer and compression system, in accordance with an embodiment of the present invention. At operation 2010 the system receives a WRITE FILE ATTRIBUTES command from an NGS application, such as inter alia NGS application 220 of FIG. 4, specifying a name and location of a native NGS file in a storage system, and a set of attributes. Generically, for a file access protocol the READ FILE ATTRIBUTES command is of the form
null writeFileAttributes(name fileName, location directoryLocation, fileAttributes attributes).
   At operation 2020 the system sends a command to the storage system, to write the specified attributes for one or more encoded files corresponding to the specified native NGS file, in the specified location. It will be appreciated that in some embodiments of the present invention, a native NGS file may correspond to more than one encoded file. At operation 2030 the system receives one or more write file attribute acknowledgements from the storage system. At operation 2040 the system sends a write file attributes acknowledgement to the NGS application.

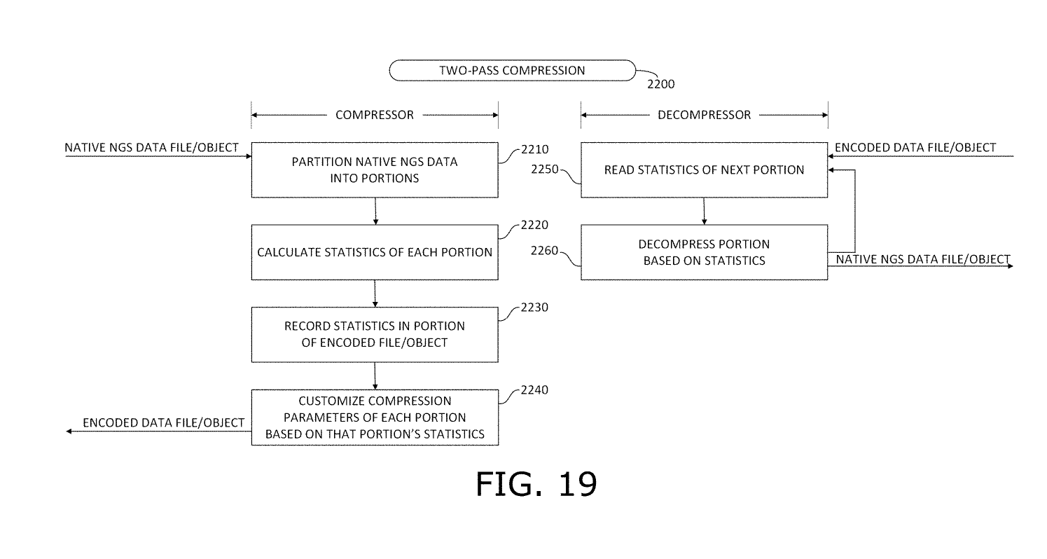

Reference is made to FIG. 18, which is a simplified flowchart of a method 2100 for performing a READ FILE SYSTEM INFORMATION operation, performed by an NGS storage, transfer and compression system, in accordance with an embodiment of the present invention. At operation 2110 the system received a READ FILE SYSTEM INFORMATION command from an NGS application, such as inter alia NGS application 220 of FIG. 4, to read the file system information of a storage system. Generically, for a file access protocol the READ FILE SYSTEM INFORMATION command is of the form
fileSystemInformation readFileSystemInformation ( ).
   At operation 2120 the system sends one or more commands to the storage system, to read file system information. At operation 2130 the system receives one or more responses from the storage system. At operation 2140 the system determines the requested file system information from the one or more responses received at operation 2130. At operation 2150 the system sends the thus-determined file system information to the NGS application.

Although FIGS. 7-18 relate to operations using a file access protocol, it will be appreciated by those skilled in the art that analogous methods apply to operations using an object store protocol, including inter alia PUT BUCKET, GET BUCKET, DELETE BUCKET, POST OBJECT, PUT OBJECT, GET OBJECT, HEAD OBJECT and DELETE OBJECT.

### Compression of NGS Data

Referring back to FIG. 4, in embodiments of the present invention appliance 100 compresses files in the FASTQ format. FASTQ files are identified by file extension as specified as part of the configuration of appliance 100; typically ‘.fq’ or ‘.fastq’.

The input file may contain consecutive, complete FASTQ records. A FASTQ record has four fields, each occupying one line of text. The fields appear in the following order: (1) identifier, (2) read, (3) +identifier, and (4) quality scores. The lines are terminated by a line-feed character, without ‘carriage return’. Records are similarly separated by a ‘line feed’.

Identifiers start with a ‘@’ character, followed by up to 255 printable ASCII characters. Compression is optimized for names which are composed of tokens separated by non-alphanumerical characters such as ‘ ’ (space) and ‘:’ (colon). Each token is either alphanumerical or numerical.

Read lines contain a combination of the base-representing characters ‘A’, ‘C’, ‘G’, ‘T’ and ‘N’ (unidentified). Any of the characters in a read may be either lower case or upper case. Preferably, at decompression all bases are converted to upper case. Read lines may be up to 4095 bases long. Read lines may vary in length.

The third line of the FASTQ record consists of a ‘+’ character, optionally followed by an identifier. The identifier, if present, must be identical to the identifier in the first line.

The quality score line must be equal in length to the read line.

Quality score lines contain ASCII characters with a numerical value that is greater than or equal to 33 (the ‘!’ character) and smaller than or equal to 74 (the ‘J’ character).

The compression of reads is assisted by a reference genome. Appliance 100 may include a human genome (hg19) as reference.

Each input FASTQ file is compressed to a single compressed output file.

The output file is a binary file. The output file starts with a header that consists of a sequence of type-length-value fields that provide the following information.
software version;
algorithm version;
presence of repeated name in records' third row;
use of reference genome during compression, always ‘yes’ in normal operation;
if a reference genome was used for compression, pathname of the reference file;
if a reference genome was used for compression, checksum of the reference file;
Input FASTQ file size;
number of reads in input file;
if a reference genome was used for compression, number of reads that were mapped to the reference;
input file checksum; and
seed for input file checksum.

Compressor 140 receives as input a native NGS data file or data object from NGS application 220, and generates as output a portion of an encoded data file for storage in data storage 320. Decompressor 150 receives as input a portion of an encoded data file from data storage 320 and generates as output a native NGS data file or data object. FIGS. 14-21 illustrate several compression/decompression algorithms that are used in various embodiments of the present invention.

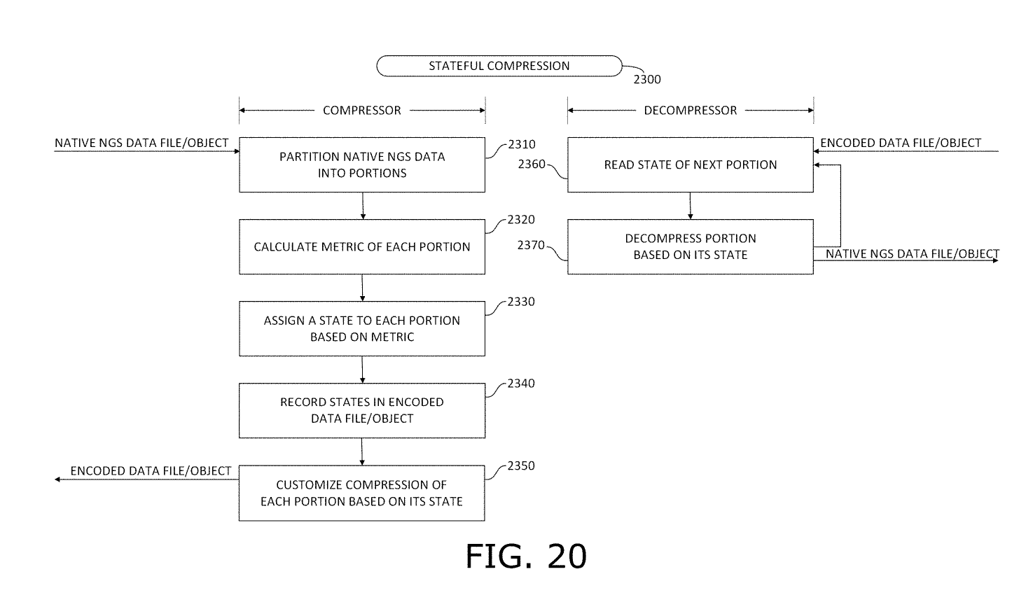

Reference is made to FIG. 19, which is a simplified flowchart of a method 2200 for two-pass compression of native NGS data, in accordance with an embodiment of the present invention. Operations 2210-2240 are performed by a data compressor, such as compressor 140 of FIG. 4. At operation 2210 the compressor receives as input a native NGS data file or data object, and partitions the data into portions. In one embodiment of the present invention, the native NGS data is partitioned so that each portion includes data of a single field type. At operation 2220 the compressor calculates statistics of each portion, in a first pass over the data. The statistics may include inter alia means and variances of data values, and correlations between data values. At operation 2230 the compressor records the statistics in a portion of an encoded data file or data object. At operation 2240 the compressor uses the statistics of each portion to customize compression parameters of that portion, in a second pass over the data, and writes the compressed data into a portion of an encoded data file or data object. E.g., with reference to an arithmetic encoder, the parameters may be the context probabilities used with the encoder.

Operations 2250 and 2260 are performed by a data decompressor, such as decompressor 150 of FIG. 4. At operation 2250 the decompressor receives as input an encoded data file or data object, and reads the statistics of the next portion of the encoded data, from the statistics recorded by the compressor at operation 2230. At operation 2260 the decompressor decompresses the encoded data using custom compression parameters for that portion based on the statistics that were read at operation 2250, and writes the decompressed data to a native NGS data file or data object. Operations 2250 and 2260 cycle through all portions of the encoded data file or data object.

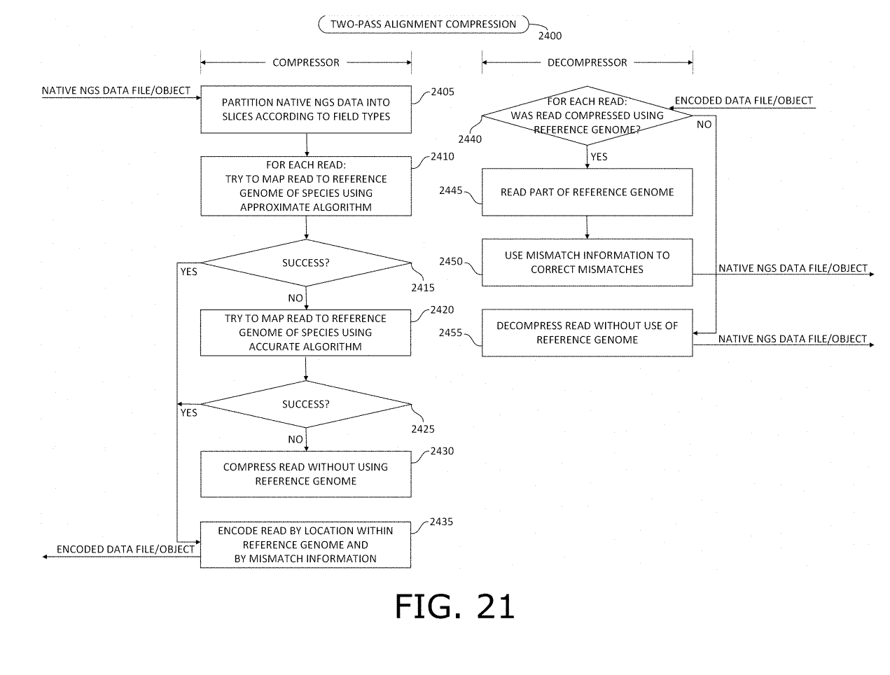

Reference is made to FIG. 20, which is a simplified flowchart of a method 2300 for stateful compression of native NGS data, in accordance with an embodiment of the present invention. Operations 2310-2350 are performed by a data compressor, such as compressor 140 of FIG. 4. At operation 2210 the compressor receives as input a native NGS data file or data object, and partitions the data into portions. In one embodiment of the present invention, the native NGS data is partitioned so that each portion includes data of a single field type. At operation 2320 the compressor calculates a metric of each portion. The metric may be inter alia a mean, a variance or a maximum of the data values. At operation 2330 the compressor assigns a state to each portion, from a plurality of states, based on that portion's metric. E.g., the state may be state-1 or state-2, respectively, depending on whether or not the metric is larger than a threshold value. At operation 2340 the compressor records the states in an encoded data file or data object. At operation 2350 the compressor uses the state of each portion to customize compression parameters of that portion, and writes the compressed data into a portion of an encoded data file or data object.

Operations 2360 and 2370 are performed by a data decompressor, such as decompressor 150 of FIG. 4. At operation 2360 the decompressor receives as input an encoded data file or data object, and reads the state of the next portion of the encoded data, from the state information recorded by the compressor at operation 2340. At operation 2370 the decompressor decompresses the encoded data using custom compression parameters for that portion based on the state that was read at operation 2360, and writes the decompressed data to a native NGS file or data object. Operations 2360 and 2370 cycle through all portions of the encoded data file or data object.

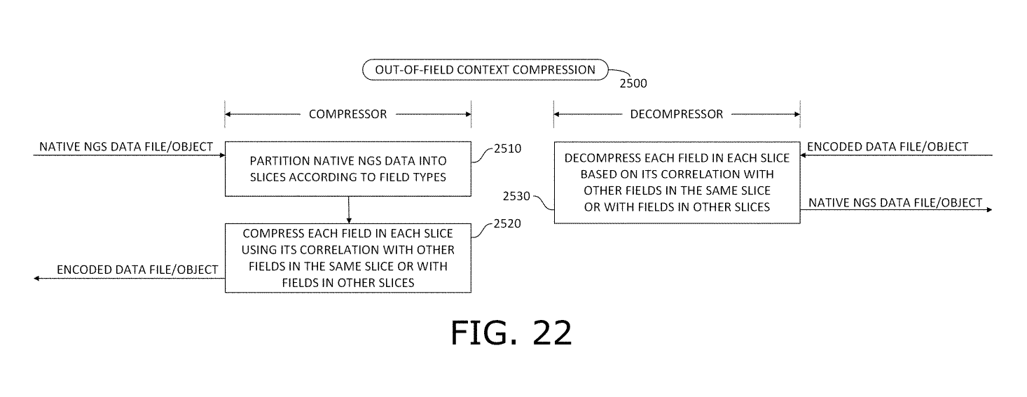

Reference is made to FIG. 21, which is a simplified flowchart of a method 2400 for two-pass alignment compression of native NGS data, in accordance with an embodiment of the present invention. Operations 2405-2435 are performed by a data compressor, such as compressor 140 of FIG. 4. At operation 2405 the compressor receives as input a native NGS data file or data object, and partitions the file into slices according to field types; e.g., tags, reads and quality score fields. At operation 2410 the compressor uses a fast approximate algorithm to map each read to a reference genome of the species. At decision 2415 the compressor decides if the mapping performed at operation 2410 is successful. If not, then at operation 2420 the compressor uses a slower accurate algorithm to map the read to the reference genome. At decision 2425 the compressor decides if the mapping performed at operation 2420 is successful. If not, then at operation 2430 the read is compressed without use of the reference genome, and the compressed data is written to an encoded data file or data object.

If at decision 2415 or at decision 2425 the compressor decides that the mapping is successful, then at operation 2435 the compressor encodes the read by location within the reference genome and by differences in the read vis-à-vis the reference genome, and the compressed data is written to an encoded data file or data object.

Operations 2440-2455 are performed by a data decompressor, such as decompressor 150 of FIG. 4. At decision 2440 the decompressor receives as input an encoded data file or data object and, for each read in the file, decides if the read was compressed using the reference genome for the species. If so, then at operation 2445 the decompressor reads the location recorded by the compressor at operation 2435, and reads the part of the reference genome to which the read was mapped. At operation 2450 the decompressor uses the difference information recorded at operation 2435 to correct the read for the differences between the read and the reference genome, and outputs the thus-corrected read to a native NGS data file or data object.

If, at decision 2440, the decompressor decides that the read was not compressed using the reference genome, then at operation 2455 the decompressor decompresses the read without use of the reference genome, and outputs the decompressed data to the native NGS file or data object.

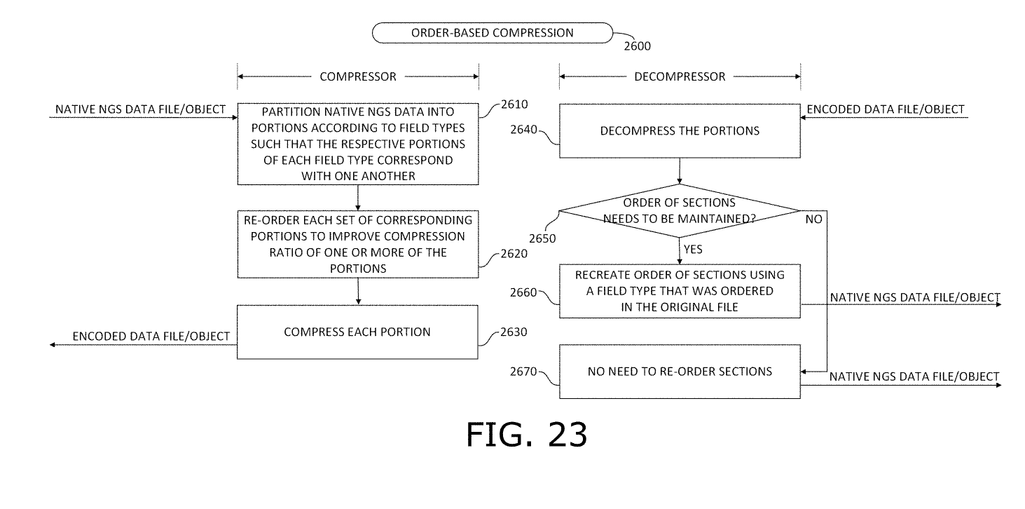

Reference is made to FIG. 22, which is a simplified flowchart of a method 2500 for out-of-field context compression of native NGS data, in accordance with an embodiment of the present invention. Operations 2510 and 2520 are performed by a data compressor, such as compressor 140 of FIG. 4. At operation 2510 the compressor receives as input a native NGS data file or data object, and partitions the file into slices according to field type, e.g., tags, reads and quality score fields. At operation 2520 the compressor compresses a field in one slice accounting for correlation or such other dependency between data values in the field with data values in other fields in the same slice, or using correlation between data values in the field with data values in fields in other slices. Each file slice may be compressed using a different compression algorithm. The compressed data is written to an encoded data file or data object.

Operation 2530 is performed by a data decompressor, such as decompressor 150 of FIG. 4. At operation 2530 the decompressor decompresses each field in each slice based on its correlation with other fields in the same slice or with fields in other slices, and outputs the decompressed data to a native NGS file or data object.

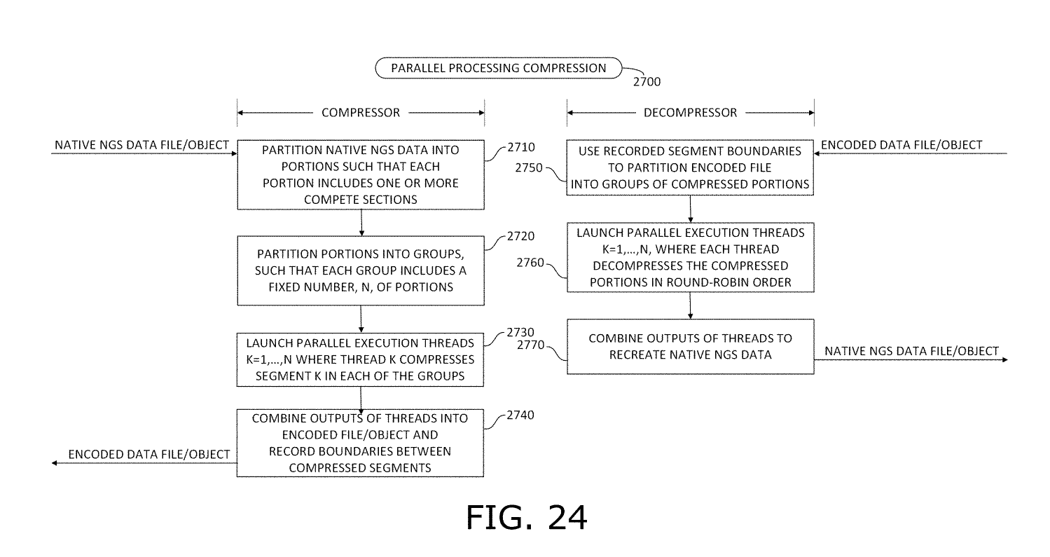

Reference is made to FIG. 23, which is a simplified flowchart of a method 2600 for order-based compression of native NGS data, in accordance with an embodiment of the present invention. Operations 2610-2630 are performed by a data compressor, such as compressor 140 of FIG. 4. At operation 2610 the compressor receives as input a native NGS data file or data object, and partitions the file into portions such that each portion contains data of a single field type.

At operation 2620 the compressor re-orders the portions so as to improve the compression ratio that can be obtained for one or more of the portions. At operation 2630 the compressor compresses each portion and writes the compressed data to an encoded data file or data object.

Operations 2640-2670 are performed by a data decompressor, such as decompressor 150 of FIG. 4. At operation 2640 the decompressor receives an encoded data file or data object and decompresses the various portions. At decision 2650 the decompressor decides if the native NGS format requires that the sections be ordered. E.g., sections in a FASTQ file may ordered in ascending order of cluster coordinates in their tag fields, and the sections in a BAM file may be ordered in ascending order of chromosome number and offset in the chromosome. If the decompressor decides at decision 2650 that the native NGS format requires ordering of the sections, then at operation 2660 the decompressor uses one of the portions, which contains a field type that was ordered in the original file, to recreate the original order of fields in all portions, and outputs the ordered and decompressed data to a native NGS file or data object. Otherwise, if the decompressor decides at decision 2650 that the native NGS format does not require ordering of the sections, then at operation 2670 the decompressed data is output to the native NGS file or data object without re-ordering the sections.

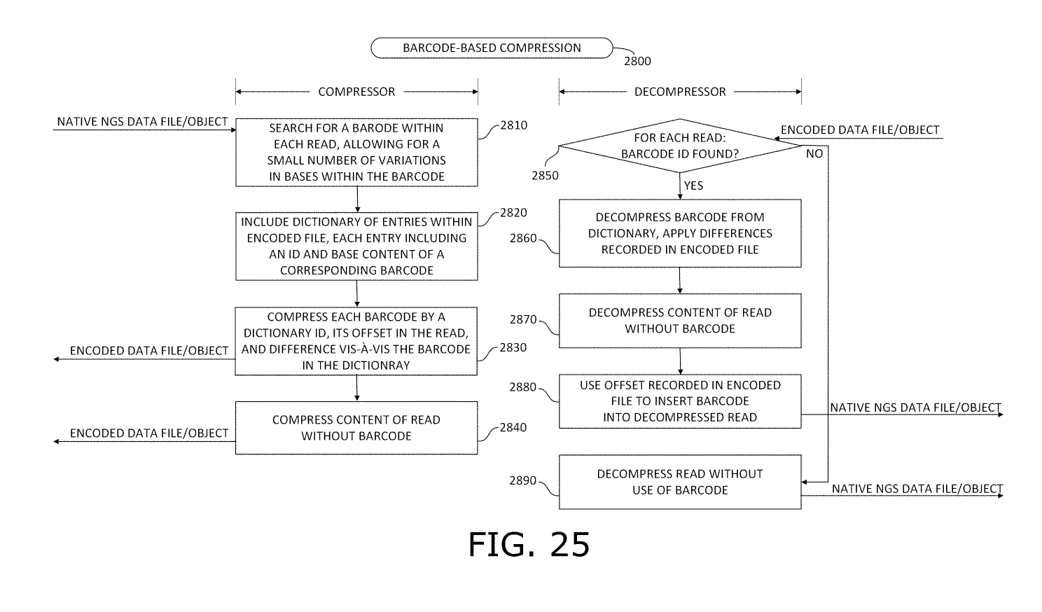

Reference is made to FIG. 24, which is a simplified flowchart of a method 2700 for parallel processing compression of native NGS data, in accordance with an embodiment of the present invention. Operations 2710-2740 are performed by a data compressor, such as compressor 140 of FIG. 4. At operation 2710 the compressor receives as input a native NGS data file or data object, and partitions the file into portions such that each portion includes one or more complete sections of the file. At operation 2720 the compressor partitions the portion into groups of portions, such that each group includes the same number, n, of portions. At operation 2730 the compressor launches n parallel execution threads, such that the k^{th} thread compresses portion k in each of the groups. At operation 2740 the compressor combines the outputs of the threads into an encoded data file or data object, and records the group boundaries between the compressed portions.

Operations 2750-2770 are performed by a data decompressor, such as decompressor 150 of FIG. 4. At operation 2750 the decompressor receives an encoded data file or data object, and uses the group boundaries recorded by the compressor at operation 2740 to partition the portions of the encoded data file or data object into groups of portions. At operation 2760 the decompressor launches n parallel execution threads, such that the threads decompress the encoded portions in round-robin order; i.e., in a first round thread 1 decompresses portion 1, thread 2 decompresses portion 2, thread n decompresses portion n, in a second round thread 1 decompresses portion n+1, thread 2 decompression portion n+2, . . . , thread n decompresses portion 2n, etc. At operation 2770 the decompressor combines the output of the threads to and writes the output to a native NGS data file or data object.

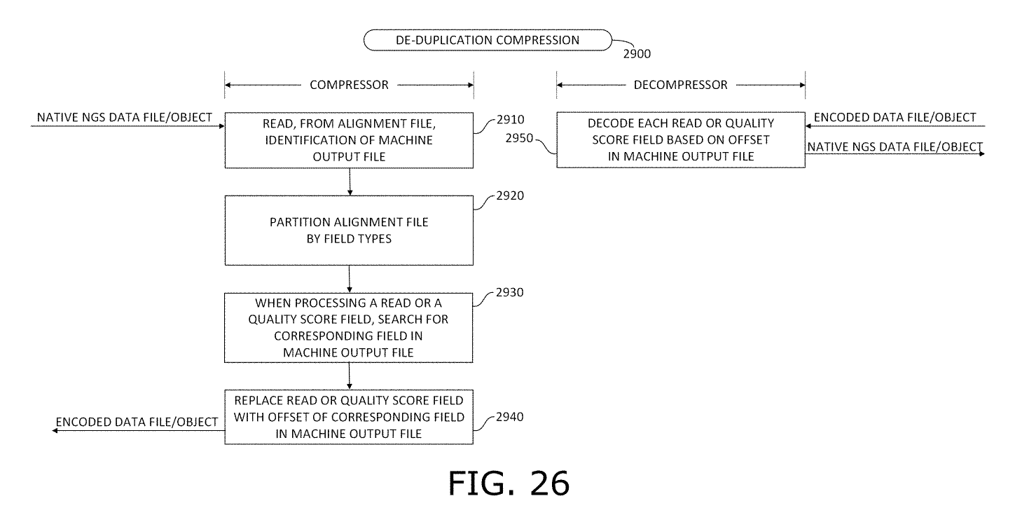

Reference is made to FIG. 25, which is a simplified flowchart of a method 2800 for barcode-based compression of native NGS data, in accordance with an embodiment of the present invention. Operations 2810-2840 are performed by a data compressor, such as compressor 140 of FIG. 4. At operation 2810 the compressor receives as input a native NGS data file or data object, and searches for a barcode within each read, allowing for a small number of variations in bases within the barcode. At operation 2820 the compressor includes a barcode dictionary within the encoded data file or data object; i.e., a dictionary of entries, each entry including an ID for a barcode and the base content of that barcode. At operation 2830 the compressor compresses each barcode by an ID in the dictionary, an offset in the read, and any differences between the barcode and the base content of the dictionary entry for that ID, and writes the compressed data into the encoded data file or data object. At operation 2840 the compressor compresses the non-barcode contents of the read, and writes the compressed data into the encoded data file or data object.

Operations 2850-2890 are performed by a data decompressor, such as decompressor 150 of FIG. 4. At decision 2850 the decompressor receives an encoded data file or data object, searches each encoded read, and decides if a barcode ID is found. If so, then at operation 2860 the decompressor decompresses the barcode in the compressed dictionary that has that ID, and applies the differences that were recorded in the file by the compressor at operation 2830. At operation 2870 the decompressor decompresses the non-barcode content of the read. At operation 2880 the decompressor uses the offset that was recorded in the file by the compressor at operation 2830, to inset the barcode into the proper location in the decompressed read, and outputs the decompressed data to a native NGS data file or data object. If, at decision, 2850, the decompress decides that a barcode ID is not found in the read, then at operation 2890 the decompressor decompresses the read without use of a barcode, and outputs the decompressed data to the native NGS data file or data object.

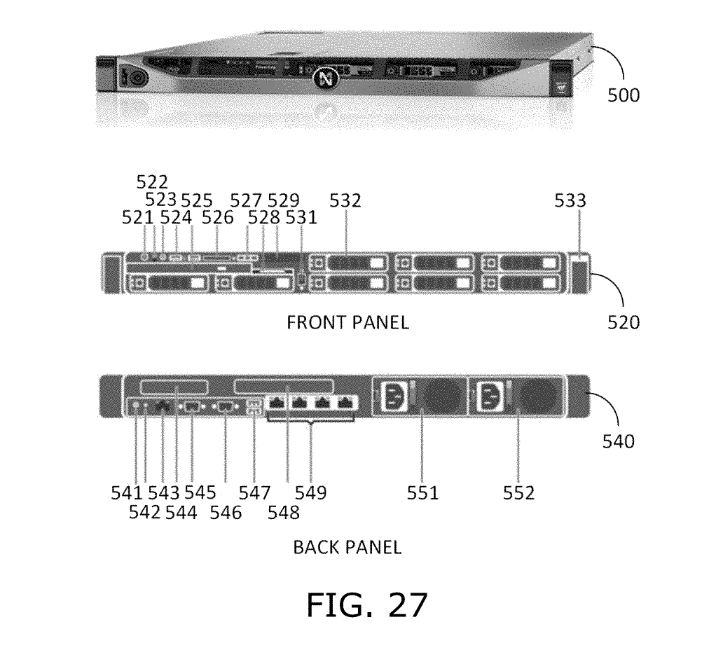

Reference is made to FIG. 26, which is a simplified flowchart of a method for de-duplication compression of native NGS data, in accordance with an embodiment of the present invention. In NGS applications, a machine output file is processed to generate an alignment file. The machine output file and alignment file have certain fields that are common to both files. The algorithm of FIG. 26 uses this commonality to reduce encoded file size in cases where the application keeps both the machine output file and the alignment file. The algorithm of FIG. 26 uses a free-form optional field in the native alignment file format to record an identifier of the machine output file that was input to the aligner. E.g., the identifier may be written in a one-line comment field in the header section of a SAM or BAM file.

Operations 2910-2940 are performed by a data compressor, such as compressor 140 of FIG. 4. At operation 2910 the compressor receives as input a native alignment file or alignment object, and reads the identifier of the corresponding machine output file. At operation 2920 the compressor partitions the alignment file by field types. At operation 2930 the compressor processes field types that appear in the machine output file by searching for their corresponding fields in the machine output file. At operation 2940 the compressor encodes the fields by the offset of the corresponding fields in the machine output file.

Operation 2950 is performed by a data decompressor, such as decompressor 150 of FIG. 4. At operation 2950 the decompressor receives an encoded alignment file or alignment object and decompresses field types that appear in the corresponding machines output file by using their encoded offset in the machine output file, and outputs the decompressed data to a native NGS alignment file or alignment object.

### Hardware Embodiment

The appliance of FIG. 4 may be implemented in a software package for installation on user-provided hardware, e.g., as a CentOS RPM software package. Alternatively, the appliance of FIG. 4 may be implemented in hardware.

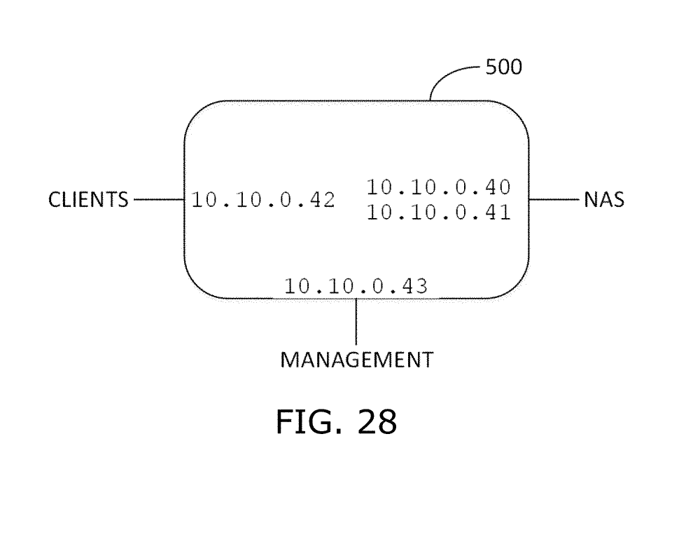

Reference is made to FIG. 27, which is an illustration of a hardware version 500 of the appliance of FIG. 4, showing front panel 520 and back panel 540 interfaces, in accordance with an embodiment of the present invention. Appliance 500 is shown in FIG. 27 housed in a 1U rack-mounted enclosure.

In embodiments of the present invention, appliance 500 has the specifications provided in TABLE I hereinbelow. Front panel 520 includes the interfaces provided in TABLE II hereinbelow. Back panel 540 includes the interfaces provided in TABLE III hereinbelow.

TABLE I
Specifications for appliance 500

| | |
|---|---|
| power supply | single supply, or |
| | dual supply in hot-spare configuration |
| power rating | 750 W |
| supply voltage | 100-240 V, auto-ranging, 50/60 Hz |
| power dissipation | 2891 BTU/hour maximum |
| operating temperature | 10° C. to 35° C. |

TABLE II
Front pane 520 interfaces

| Element | Feature | Icon | Description |
|---|---|---|---|
| 521 | power-on | [symbol] | The power-on indicator lights when the |
| | indicator, | | system power is on. The power button |
| | power button | | controls the power supply output to the |
| | | | system. |
| 522 | NMI button | [symbol] | Non-maskable Interrupt button. |
| 523 | system | [symbol] | The identification buttons on the front and |
| | identification | | back panels are used to locate a particular |
| | button | | enclosure within a rack. When one of |
| | | | these buttons is pressed, the LCD panel |
| | | | on the front and the system status |
| | | | indicator on the back flashes blue until |
| | | | one of the buttons is pressed again. |
| | | | Press to toggle the system ID to ON or |
| | | | OFF. If the system stops responding |
| | | | during power-on self-test, press and hold |
| | | | the system ID button for more than five |
| | | | seconds to enter BIOS progress mode. |
| 524 | USB | [symbol] | Use for connecting a keyboard for initial |
| | management | | configuration. |
| | ports | | |
| 525 | optical drive | | |
| | (optional) | | |
| 526 | SD vFlash | [symbol] | |
| | media card | | |
| | slot | | |
| 527 | LCD menu | | |
| | buttons | | |
| 528 | information | | A slide-out label panel, with system |
| | tag | | information, such as service tag, NIC, and |
| | | | MAC address. |
| 529 | LCD panel | | Displays enclosure hardware ID and |
| | | | hardware status and error messages. The |
| | | | LCD lights blue during normal system |
| | | | operation. When the system needs |
| | | | attention, the LCD lights amber and the |
| | | | LCD panel displays an error code |
| | | | followed by descriptive text. |
| 531 | video output | [symbol] | VGA display connection |
| 532 | hard drive | | One 2.5 inch hard-drive installed. The |
| | bays | | hard-drive has two indicators: Activity and |
| | | | Status |
| 533 | mounting | | |
| | brackets | | |

TABLE III
Back pane 540 interfaces

| Ele- | | | |
|---|---|---|---|
| ment | Feature | Icon | Description |
| 541 | system | [symbol] | The identification buttons on the front and |
| | identification | | back panels can be used to locate a |
| | button | | particular enclosure within a rack. When |
| | | | one of these buttons is pressed, the LCD |
| | | | panel on the front and the system status |
| | | | indicator on the back flashes blue until |
| | | | one of the buttons is pressed again. Press |
| | | | to toggle the system ID to ON or OFF. If |
| | | | the system stops responding during |
| | | | power-on self-test, press and hold the |
| | | | system ID button for more than five |
| | | | seconds to enter BIOS progress mode. |
| 542 | system | | |
| | identification | | |
| | port | | |
| 543 | dedicated | [symbol] | |
| | management | | |
| | port | | |
| 544 | PCIe expansion | | |
| | card slot | | |
| 545 | serial | [symbol] | |
| | communication | | |
| | port | | |
| 546 | video output | [symbol] | VGA display connection. |
| 547 | USB | [symbol] | Used for connecting a keyboard for initial |
| | connectors (2) | | configuration. |
| 548 | PCIe expansion | | |
| | card slot | | |
| 549 | LAN ports | [symbol] | Four LAN ports: |
| | | | Two 10/100/1000 Mbps Ethernet ports |
| | | | Two 100 Mbps/1 Gbps/10 Gbps Ethernet |
| | | | SFP+ slots. |
| | | | Depending on the ordered configuration, |
| | | | the slots may remain unpopulated (for |
| | | | use of a direct attach connection) or |
| | | | populated with an optical SFP. |
| 551 | power supply | | Voltage input: 100-240 V AC, auto- |
| | | | ranging, 50/60 Hz |
| | | | Power rating: 750 W |
| 552 | hot-spare | | Voltage input: 100-240 V AC, auto- |
| | power supply | | ranging, 50/60 Hz |
| | (optional) | | |

Appliance 500 has four network interfaces, as follows: two 100 Mbps/1 Gbps/10 Gbps Ethernet SFP+ interfaces on the back panel named eth0 and eth1, respectively; and
two 10/100/1000 Mbps Ethernet interfaces, on the back panel named eth2 and eth3, respectively.

In a typical installation
interface eth0, 10 Gbps, connects appliance 500 to a NAS;
interface eth1, 10 Gbps connects appliance 500 to storage clients; and
interface eth2, 1 Gbps is used for management.

Reference is made to FIG. 28, which is an exemplary IP address configuration for appliance 500, in accordance with an embodiment of the present invention. Interface eth0, which is used for communication with the NAS, is configured with two IP addresses (aliases); namely,
a first address, referred to as the “privileged address”, used by appliance 500 to access the compressed file system and to perform privileged operations on the original file system; and
a second address, referred to as the “unprivileged address”, used by appliance 500 for communication with the NAS as a proxy of clients.

E.g., the two files defining eth0 and its alias eth0:0 may be as follows:

The Privileged Address for eth0
DEVICE=eth0
HWADDR=EC:F4:BB:DE:83:A8
TYPE=Ethernet
UUID=5cc8903a-42ab-40a6-b93f-5440e924a300
ONBOOT=yes
NM_CONTROLLED=no
BOOTPROTO=static
IPADDR=10.10.0.40
PREFIX=24
DEFROUTE=no
   The Unprivileged Address for eth0
DEVICE=eth0:0
ONBOOT=yes
NM_CONTROLLED=no
BOOTPROTO=static
IPADDR=10.10.0.41
PREFIX=24
DEFROUTE=no

Appliance 500 may be configured to mount the NAS compressed file system by adding the following line to /etc/fstab:
Server:export /mnt/nas nfs
Appliance 500 does not mount the original file system: rather, it accesses it as a client RPC proxy.

The appliance 500 proxy may be configured using a configuration file similar to the example provided below. Lines starting with ‘#’ are comments. Other lines consist of space-separated name-value pairs.

| # Example configuration file for appliance 500 | |
|---|---|
| # Storage system | |
| # IP address or name | |
| storage_address | 10.10.0.20 |
| # Original file system export | |
| server_export | /vol1/fastq |
| # eth0 unprivileged address (specified in eth0:0). Appliance | |
| # 500 uses this address when it accesses the NAS as a proxy of | |
| # clients | |
| client_proxy_address | 10.10.0.41 |
| # Size of uncompressed fastq file cache, in GB | |
| cache_size | 200 |
| # FASTQ file extensions. Entries are case sensitive and must | |
| # be comma seperated with no spaces. | |
| fastq_extensions | fastq,FASTQ,fq,FQ |
| # The location, within the compressed file system mount-point, | |
| # of compressed fastq files | |
| cfq_dir | /mnt/nas/cfq |
| # The location, within the compressed file system mount-point, | |
| # of the journal file | |
| journal_file_dir | /mnt/nas/journal |

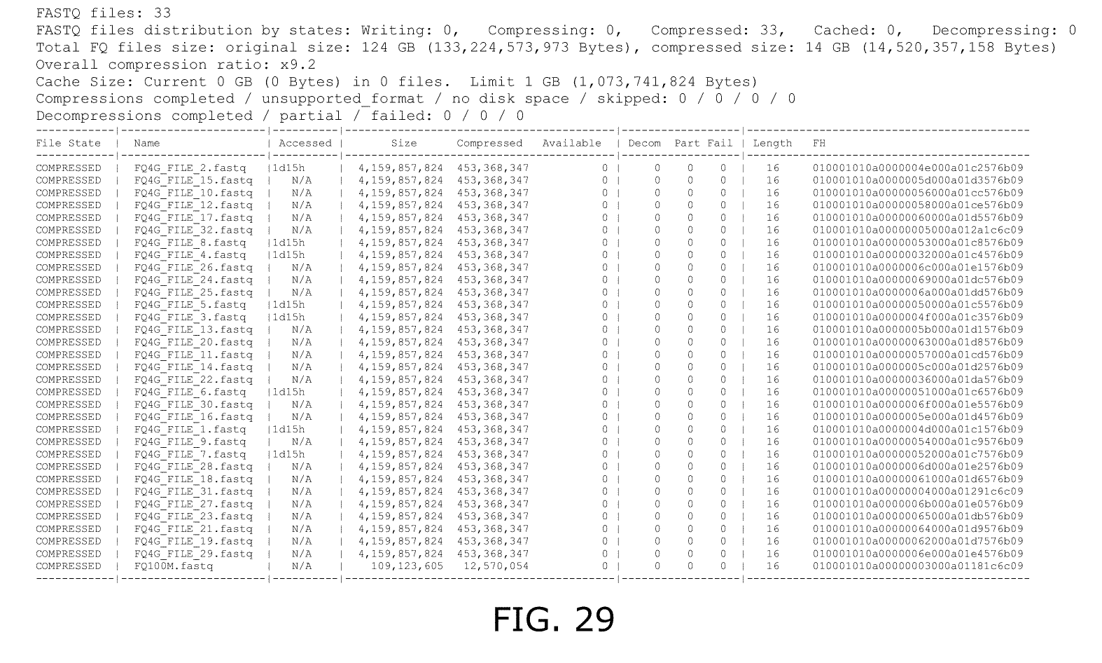

Reference is made to FIG. 29, which is a sample of summary information and file list output by appliance 500, in accordance with an embodiment of the present invention. TABLE IV hereinbelow lists the types of information shown in FIG. 29.

TABLE IV
Summary information provided by appliance 500

| | |
|---|---|
| FASTQ files | The number of FASTQ files |
| FASTQ file distribution by | Out of the total number of FASTQ files |
| state Writing | The number of files currently being |
| | written to by clients |
| Compressing | The number of files currently being |
| | compressed |
| Compressed | The number of files currently stored in |
| | compressed format |
| Cached | The number of files currently in the |
| | cache (out of the compressed files) |
| Decompressing | The number of files currently being |
| | decompressed (out of the compressed |
| | files) |
| Total FASTQ files size | The total size of FASTQ files in their |
| | native format |
| Compressed size | The total volume of FASTQ files in |
| | compressed format |
| Overall compression ratio | FASTQ file total size divided by total |
| | FASTQ file compressed size |
| Cache size | Total size and number of files in the |
| | cache |
| Limit | Cache size limit |
| Compressions completed/ | The number of compression operations |
| unsupported format/no disk | that were completed successfully or not - |
| space/skipped | due to unsupported FASTQ format/ |
| | lack of disk space/skipped for other |
| | reasons |
| Decompressions completed/ | The number of decompression |
| partial/failed | operations that were completed/were |
| | not completed (aborted by client)/ |
| | failed |

The file list in FIG. 29 includes columns for file state, file name, time since last access, native file size, compressed file size, availability, decompression completed/partial/failed, length of file handle, and NFS file handle.

In the foregoing specification, the invention has been described with reference to specific exemplary embodiments thereof. It will, however, be evident that various modifications and changes may be made to the specific exemplary embodiments without departing from the broader spirit and scope of the invention. Accordingly, the specification and drawings are to be regarded in an illustrative rather than a restrictive sense.

APPENDIX A

| | |
|---|---|
| 1 | Connection thread |
| 2 | ----------------- |
| 3 | |
| 4 | Do forever { |

| | |
|---|---|
| 5 | Wait on message queues from client connection, NAS connection and Proxy Thread input |
| 6 | if (message from client connection) { |

| | |
|---|---|
| 7 | Record RPC XID and overwrite |
| 8 | if (MOUNT command) { |

| | |
|---|---|
| 9 | if (mount directory == configuration file entry) forward to NAS |
| 10 | else respond with error code |

| | |
|---|---|
| 11 | } |
| 12 | else if (general file system command such as FSSTAT) { |

| | |
|---|---|
| 13 | forward to NAS |

| | |
|---|---|
| 14 | } |
| 15 | else if (non-FASTQ and non-BAM file - as determined by name suffix or unidentified file handle) { |

| | |
|---|---|
| 16 | if (CREATE or RENAME or REMOVE or LOOKUP or READDIR or READDIRPLUS command) { |

| | |
|---|---|
| 17 | update file tree data structure |

| | |
|---|---|
| 18 | } |
| 19 | forward to NAS |

| | |
|---|---|
| 20 | } |
| 21 | else switch (command type) { |

| | |
|---|---|
| 22 | GETATTR: forward to NAS |
| 23 | SETATTR: if sets size respond with error message; else forward to NAS |
| 24 | LOOOKUP: forward to NAS |
| 25 | ACCESS: |
| 26 | READLINK: |
| 27 | SYMLINK: forward to NAS |
| 28 | MKDIR: forward to NAS |
| 29 | REMOVE: forward to NAS |
| 30 | RMDIR: forward to NAS |
| 31 | RENAME: forward to NAS |
| 32 | READDIR: |
| 33 | READDIRPLUS: forward to NAS |
| 34 | CREAT: if (disk full) send error response; else forward to NAS |
| 35 | WRITE: |
| 36 | COMMIT: if (file state != Writing) send error response; else forward to NAS |
| 37 | READ: { if (file state == Writing or Compressing or Uncompressed) forward to NAS |

| | |
|---|---|
| 38 | else { |

| | |
|---|---|
| 39 | if (data available in cache) forward to NAS |
| 40 | else queue and send Decompress request for data range to Server thread |

| | |
|---|---|
| 41 | } |

| | |
|---|---|
| 42 | } |

| | |
|---|---|
| 43 | } |

| | |
|---|---|
| 44 | } else if (message from NAS connection) { |

| | |
|---|---|
| 45 | Restore XID |
| 46 | if (MOUNT response) { |

| | |
|---|---|
| 47 | record handle of tree root |
| 48 | forward to client |

| | |
|---|---|
| 49 | } |
| 50 | else if (general file system response, e.g. FSSTAT) { |

| | |
|---|---|
| 51 | forward to client |

| | |
|---|---|
| 52 | } |
| 53 | else if (non-FASTQ and non-BAM file - as determined by name suffix or unidentified file handle) { |

| | |
|---|---|
| 54 | forward to client |

| | |
|---|---|
| 55 | } |
| 56 | else switch (response type) { |

| | |
|---|---|
| 57 | GETATTR: modify response to show original file size and true last modified time; forward to client |
| 58 | SETATTR: if accepted by NAS, update FASTQ and BAM table; forward to client |
| 59 | LOOKUP: update tree data structure; forward to client |
| 60 | ACCESS: |
| 61 | READLINK: |
| 62 | SYMLINK: forward to client |
| 63 | MKDIR: if successful, update tree data structure; forward to client |
| 64 | REMOVE: if successful, send Remove message to Server thread; forward to client |
| 65 | RMDIR: if successful, delete from tree data structure; forward to client |
| 66 | RENAME: if successful, update tree data structure, forward to client |
| 67 | READDIR: |
| 68 | READDIRPLUS: modify file information to show uncompressed size and true last modified time |

| | |
|---|---|
| 69 | forward to client |

| | |
|---|---|
| 70 | CREATE: if (successful) add file table entry and send Create message to Server thread |

| | |
|---|---|
| 71 | forward to client |

| | |
|---|---|
| 72 | WRITE: |
| 73 | COMMIT: update last-modified time stamp in FASTQ table entry; forward to client |
| 74 | READ: update last access time stamp in FASTQ table entry; forward to client |

| | |
|---|---|
| 75 | } |

| | |
|---|---|
| 76 | } |
| 77 | else { * Message from Server thread * |

| | |
|---|---|
| 78 | switch (message type) : |

| | |
|---|---|
| 79 | Decompress progress: un-queue and forward to NAS READ commands for which data just became available |
| 80 | Abort: Un-queue file's read messages and reply with an error response |

| | |
|---|---|
| 81 | } |

| | |
|---|---|
| 82 | } |
| 83 | |
| 84 | Server thread |
| 85 | ------------- |
| 86 | |
| 87 | Do forever { |

| | |
|---|---|
| 88 | Wait on message queues from Connection threads, Compression/Decompression process and periodic timer |
| 89 | if (message from Connection thread) { |

| | |
|---|---|
| 90 | switch (message type) { |

| | |
|---|---|
| 91 | Create: file state = Writing; move file to Writing list |
| 92 | Decompress: if (file state != Decompressing) { |

| | |
|---|---|
| 93 | if (cache is full) delete least recently used files |
| 94 | file state = Decompresssing |
| 95 | move file to Decompressing list |

| | |
|---|---|
| 96 | } |
| 97 | send Decompress request to Compression/Decompression thread with data range for decompression |

| | |
|---|---|
| 98 | Remove: send Abort message to Compression/Decompression thread |

| | |
|---|---|
| 99 | send Abort message to all reading Connection threads |
| 100 | remove file table entries |

| | |
|---|---|
| 101 | } else if (idle timer expired) { |

| | |
|---|---|
| 102 | for (each idle file in Decompressing list) send Abort message to Compression/Decompression thread |
| 103 | for (each idle file in Writing list) { |

| | |
|---|---|
| 104 | send Compress request to Compression/Decompression process |
| 105 | move file to Compressing list |

| | |
|---|---|
| 106 | } |

| | |
|---|---|
| 107 | } |
| 108 | else { * message from Compression/Decompression thread * |

| | |
|---|---|
| 109 | Compress start report: note name of Compression/Decompression thread message FIFO |
| 110 | Compress end report: remove ‘.tmp’ suffix from file name and move it to Compressed list |
| 111 | Decompress start report: note name of Compression/Decompression thread message FIFO |
| 112 | Decompress report: record newly available data for read |

| | |
|---|---|
| 113 | send Decompress progress messages to reading Connection threads |
| 114 | if (end of file reached) move file to uncompressed list |

| | |
|---|---|
| 115 | Abort acknowledge: clean-up |
| 116 | } |

| | |
|---|---|
| 117 | } |

| | |
|---|---|
| 118 | |
| 119 | Master thread |
| 120 | ------------- |
| 121 | |
| 122 | Do forever { |

| | |
|---|---|
| 123 | Wait on message queues from Server thread |
| 124 | switch (message type) { |

| | |
|---|---|
| 125 | Compress request: create compressing Compression/Decompression thread with input of file handle |
| 126 | Decompress request: create decompressing Compression/Decompression thread with inputs of file name |
| 127 | and data range |

| | |
|---|---|
| 128 | } |

| | |
|---|---|
| 129 | } |
| 130 | |
| 131 | Compression/Decompression thread |
| 132 | -------------------------------- |
| 133 | |
| 134 | if (created for compression) { |

| | |
|---|---|
| 135 | create file with ‘.tmp’ suffix |
| 136 | send Compression start report to Server thread with input FIFO name |
| 137 | compress file |
| 138 | send Compression end report to Server thread |
| 139 | terminate |

| | |
|---|---|
| 140 | } |
| 141 | else { * created for decompression * |

| | |
|---|---|
| 142 | send Decompression start report to Server thread with input FIFO name |
| 143 | while (decompressing data range) { |

| | |
|---|---|
| 144 | Check for input message from Server thread |
| 145 | if (received Decompress request message) update data range |
| 146 | if (received Abort message) send Abort Acknowledge message; terminate |
| 147 | send Decompress progress reports to Server thread |
| 148 | if (reached end of file) send Decompress progress report with End Of File flag; terminate |

| | |
|---|---|
| 149 | } |

| | |
|---|---|
| 150 | } |

What is claimed is:

1. A computer appliance for storage, transfer and compression of next generation sequence (NGS) data, comprising:
a front-end interface communicating with a client computer via a first storage access protocol;
a back-end interface communicating with a storage system via a second storage access protocol;
a compressor receiving native NGS data from an application running on the client computer via said front-end interface, the application being programmed to process native NG data, adding a compressed form of the native NGS data into a portion of an encoded data file or data object, and storing the portion of the encoded data file or data object in the storage system via said back-end interface; and
a decompressor receiving a portion of an encoded data file or data object from the storage system via said back-end interface, decompressing the portion of the encoded data file or data object to generate therefrom native NGS data, and transmitting the native NGS data to the client via said front-end interface, for use by the application running on the client.

2. The appliance of claim 1 further comprising a cache manager for managing a cache of portions of decoded NGS data files or data objects, wherein said decompressor transmits cached native NGS data to the client, instead of generating the native NGS data, when the requisite native NGS data is resident in the cache.

3. The appliance of claim 1 wherein the cache resides on the storage system.

4. The appliance of claim 1 wherein the cache does not reside on the storage system.

5. The appliance of claim 1 wherein the storage system is a network file server.

6. The appliance of claim 1 wherein the storage system is a cloud-based server.

7. The appliance of claim 1 wherein the first storage access protocol is a file access protocol.

8. The appliance of claim 1 wherein the first storage access protocol is an object store protocol.

9. The appliance of claim 1 wherein the storage system is a file-based storage system, and the second storage access protocol is a file access protocol.

10. The appliance of claim 1 wherein the storage system is an object-based storage system, and the second storage access protocol is an object store protocol.

11. The appliance of claim 1 wherein the native NGS data is formatted in accordance with a genomics file format.

12. The appliance of claim 11 wherein the genomics file format is a member of the group consisting of a BAM file format, a FASTQ file format, and a SAM file format.

13. The appliance of claim 1 comprising a cloud-based server.

14. A non-transitory computer readable medium storing instructions, which, when executed by a processor of a computer appliance, cause the processor to:
in response to receiving a write request from an application running on a client computer, the application being programmed to process native NGS data:
obtain native NGS data from the application;
read a portion of an encoded data file or data object from a storage system;
modify the portion of the encoded data file or data object, comprising adding a compressed form of the native NGS data into the portion of the encoded data file or data object; and
transmit the modified portion of the encoded data file or data object for storage in the storage system; and
in response to receiving a read request from the application:
read a portion of an encoded data file or data object from the storage system;
decompress the portion of the encoded data file or data object and generate therefrom native NGS data; and
transmit the native NGS data to the application.

15. The computer readable medium of claim 14, wherein the instructions further cause the processor to, in response to receiving a request for attributes of an NGS data file or data object from the application:
query the storage system for the attributes of a respective encoded NGS data file or data object stored in the storage system;
determining the attributes of a corresponding decoded NGS data file or data object; and
transmitting the thus-determined attributes to the application.

16. The computer readable medium of claim 14, further comprising managing a cache of portions of decoded NGS data files or data objects, wherein the processor transmits cached native NGS data to the application, instead of generating the native NGS data, when the requisite native NGS data is resident in the cache.

17. The computer readable medium of claim 14 wherein the native NGS data is formatted in accordance with a genomics file format.

18. The computer readable medium of claim 17 wherein the genomics file format is a member of the group consisting of a BAM file format, a FASTQ file format, and a SAM file format.
